(19) United States
(12) Patent Application Publication
(10) Pub. No.: US 2017/0271613 A1
(43) Pub. Date: Sep. 21, 2017

(54) ORGANIC LIGHT-EMITTING DEVICE

(71) Applicant: JOLED INC., Tokyo (JP)

(72) Inventors: Hiroyuki AJIKI, Tokyo (JP); Hideyuki SHIRAHASE, Tokyo (JP); Jun HASHIMOTO, Tokyo (JP)

(21) Appl. No.: 15/532,317

(22) PCT Filed: Dec. 3, 2015
(86) PCT No.: PCT/JP2015/006007

§ 371 Date: Jun. 1, 2017

(30) Foreign Application Priority Data
Dec. 3, 2014 (JP) 2014-244659

(51) Int. Cl. H01L 51/52; H01L 51/56

(52) U.S. Cl. CPC H01L 51/5234; H01L 51/5225; H01L 51/5218; H01L 51/56; H01L 2251/558; H01L 2251/308; H01L 2251/305; H01L 2251/301; H01L 51/5253; H01L 27/3246

(57) ABSTRACT

An organic light-emitting device includes a substrate, a first electrode, an organic light-emitting layer, an organic functional layer, a translucent electrically-conductive film, and a second electrode. The first electrode is disposed over the substrate. The organic light-emitting layer is disposed over the first electrode. The organic functional layer is disposed over the organic light-emitting layer. The translucent electrically-conductive film is disposed on the organic functional layer and is in contact with the organic functional layer. The second electrode is composed of a metal material or an alloy material and is disposed over the translucent electrically-conductive film. Furthermore, in the translucent electrically-conductive film, the film thickness is equal to or larger than 60 nm and the residual stress is in a range of −400 MPa to +400 MPa.

### TECHNICAL FIELD

The present invention relates to an organic light-emitting device and particularly to an organic light-emitting device obtained by employing a metal layer or an alloy layer as an electrode on the light extraction side.

### BACKGROUND ART

In recent years, development of organic light-emitting devices such as organic electro luminescence (EL) panels and organic EL illumination has been being actively carried out. One example of the structure of an organic light-emitting device relating to a conventional technique will be described by using FIG. 21(a).

As illustrated in FIG. 21(a), the organic light-emitting device has a configuration in which, between an anode 903 and a cathode 910, a hole injection layer 904, a hole transport layer 905, an organic light-emitting layer 907, and an electron transport layer 908 are sequentially disposed from the side of the anode 903.

Here, in the organic light-emitting device of a type in which light is emitted from the side of the cathode 910, conventionally a translucent electrically-conductive layer of indium tin oxide (ITO) or the like is used as the cathode. However, in recent years, research and development to employ a metal thin film also as the cathode 910 have been carried out (PTLs 1 and 2). This aims at further improvement in the light emission efficiency by a cavity, improvement in the chromaticity, and so forth.

### CITATION LIST

### Patent Literatures

[PTL 1]

### JP 2009-059584A

[PTL 2]

### JP 2011-204646A

### SUMMARY

### Technical Problems

However, in the case of attempting to employ the cathode 910 formed of a metal thin film, cathode quenching readily occurs and the lowering of the light emission efficiency is caused if a gap G1 between the organic light-emitting layer 907 and the cathode 910 is small.

Against such problems, the inventors made studies concerning whether or not it is possible to employ a configuration like one illustrated in FIG. 21(b). Specifically, the inventors made studies concerning employment of a configuration in which the thickness of an electron transport layer 918 is increased in order to ensure such a gap G2 between the organic light-emitting layer 907 and the cathode 910 that cathode quenching occurs less readily as illustrated in FIG. 21(b). As a result of the studies, optical loss and electrical loss become large with this configuration and the employment is difficult.

Next, the inventors made studies concerning whether or not it is possible to employ a configuration like one illustrated in FIG. 21(c). The inventors made studies concerning employment of a configuration in which a translucent electrically-conductive film 909 of ITO or the like is interposed between the electron transport layer 908 and the cathode 910 in order to ensure a gap G3 between the organic light-emitting layer 907 and the cathode 910 as illustrated in FIG. 21(c). As a result of the studies, as illustrated in FIG. 22, depending on the film thickness of the translucent electrically-conductive film 909, a film defect such as film separation often occurs in the electron transport layer 908 under the translucent electrically-conductive film 909.

Regarding the occurrence of quenching, it is feared that the quenching similarly occurs not only when the cathode is disposed on the light extraction side but also when the anode is disposed. That is, it is conceivable that a similar problem is caused if an electrode formed of a metal thin film is used.

The present invention is made to intend to solve the above-described problems and aims at providing an organic light-emitting device with a configuration with which the occurrence of a film defect of an organic functional layer under a translucent electrically-conductive film can be suppressed while the occurrence of quenching can be suppressed by disposing the translucent electrically-conductive film between an electrode and an organic light-emitting layer.

### Solution to Problems

An organic light-emitting device according to one mode of the present invention includes a substrate, a first electrode, an organic light-emitting layer, an organic functional layer, a translucent electrically-conductive film, and a second electrode.

The first electrode is disposed over the substrate. The organic light-emitting layer is disposed over the first electrode. The organic functional layer is disposed over the organic light-emitting layer. The translucent electrically-conductive film is disposed over the organic functional layer and is in contact with the organic functional layer. The second electrode is composed of a metal material or an alloy material and is disposed over the translucent electrically-conductive film.

Furthermore, in the organic light-emitting device according to the present mode, the film thickness of the translucent electrically-conductive film is equal to or higher than 60 [nm] and the residual stress thereof is in a range of −400 [MPa] to +400 [MPa].

### Advantageous Effect of Invention

In the organic light-emitting device according to the above-described mode, the occurrence of a film defect of the organic functional layer under the translucent electrically-conductive film can be suppressed while the occurrence of quenching is suppressed by disposing the translucent electrically-conductive film between the electrode and the organic light-emitting layer.

### BRIEF DESCRIPTION OF DRAWINGS

FIG. 1 is a schematic block diagram illustrating the configuration of an organic display device 1 according to embodiment 1.

FIG. 2 is a schematic plan view illustrating a partial configuration of a display panel 10.

FIG. 3 is a schematic sectional view illustrating a partial configuration of the display panel 10.

FIG. 4 is a schematic diagram illustrating a partial configuration of the display panel 10.

FIG. 5(a) is a diagram illustrating the relationship between the distance between an organic light-emitting layer and a cathode and quenching, and FIG. 5(b) is a diagram illustrating the relationship between the layer thickness of an electronic transport layer and the light emission efficiency.

FIG. 6 is a graph illustrating the relationship between thickness T_{L} and thickness T_{U} and the light emission luminance in a sub-pixel whose light emission color is blue (B).

FIG. 7 is a graph illustrating the relationship between the thickness T_{L} and the thickness T_{U} and the light emission luminance in a sub-pixel whose light emission color is red (R).

FIG. 8 is a graph illustrating the relationship between the thickness T_{L} and the thickness T_{U} and the light emission luminance in a sub-pixel whose light emission color is green (G).

FIG. 9 is a schematic diagram illustrating the residual stress in a translucent electrically-conductive film 109.

FIG. 10 is a step diagram illustrating part of a manufacturing process of a display panel 10.

FIG. 11 is a graph illustrating the relationship between the film deposition condition of the translucent electrically-conductive film 109 and the residual stress.

FIG. 12 is a schematic sectional view illustrating a partial configuration of a display panel 30 according to embodiment 2.

FIG. 13 is a graph illustrating the relationship between the doping concentration of Ba in an electron transport layer 308 and the light emission efficiency ratio.

FIG. 14 is a schematic sectional view illustrating a partial configuration of a display panel 35 according to embodiment 3.

FIG. 15 is a schematic sectional view illustrating a partial configuration of a display panel 40 according to embodiment 4.

FIG. 16 is a graph illustrating the relationship between layer thickness T_{Ba} of a second intermediate layer 413 and the current density.

FIG. 17 is a graph illustrating the relationship between the layer thickness T_{Ba} of the second intermediate layer 413 and the light emission efficiency ratio.

FIG. 18(a) is a graph illustrating layer thickness T_{NaF} of a first intermediate layer 412 and the luminance retention, and FIG. 18(b) is a graph illustrating the relationship the between the layer thickness T_{NaF} of the first intermediate layer 412 and the light emission efficiency ratio.

FIG. 19 is a graph illustrating the relationship between the ratio between the layer thickness T_{Ba} and the layer thickness T_{NaF} and the light emission efficiency ratio, and FIGS. 19(a) and 19(b) are different in the material that configures a hole transport layer.

FIG. 20 is a schematic sectional view illustrating a partial configuration of a display panel 50 according to embodiment 5.

FIG. 21(a) is a schematic sectional view illustrating a partial configuration of a display panel according to a conventional technique, and FIG. 21(b) is a schematic sectional view illustrating a partial configuration of a display panel that has been studied by the inventors and includes an electron transport layer 918 whose layer thickness is large, and FIG. 21(c) is a schematic sectional view illustrating a partial configuration of a display panel that has been studied by the inventors and includes a translucent electrically-conductive film 909 interposed between an electron transport layer 908 and a cathode 910.

FIG. 22 is a diagram illustrating the appearance of film separation of an electron transport layer observed when the residual stress of a translucent electrically-conductive film was high.

### DESCRIPTION OF EMBODIMENTS

### Modes of Present Invention

An organic light-emitting device according to one mode of the present invention includes a substrate, a first electrode, an organic light-emitting layer, an organic functional layer, a translucent electrically-conductive film, and a second electrode.

The first electrode is disposed over the substrate. The organic light-emitting layer is disposed over the first electrode. The organic functional layer is disposed over the organic light-emitting layer. The translucent electrically-conductive film is disposed on the organic functional layer and is in contact with the organic functional layer. The second electrode is composed of a metal material or an alloy material and is disposed over the translucent electrically-conductive film.

Furthermore, in the organic light-emitting device according to the present mode, the film thickness of the translucent electrically-conductive film is equal to or larger than 60 [nm] and the residual stress thereof is in a range of −400 [MPa] to +400 [MPa].

In the organic light-emitting device according to this mode, by disposing the translucent electrically-conductive film whose film thickness is equal to or larger than 60 [nm] between the organic functional layer and the second electrode, the interval between the organic light-emitting layer and the second electrode can be ensured and the occurrence of quenching can be suppressed. It is more preferable to set the film thickness of the translucent electrically-conductive film to 100 [nm] or larger in terms of suppression of the occurrence of quenching.

Furthermore, in this organic light-emitting device, by setting the residual stress of the translucent electrically-conductive film in the range of −400 [MPa] to +400 [MPa], the occurrence of a defect such as film separation of the organic functional layer can be suppressed.

Therefore, in the organic light-emitting device according to the above-described mode, the occurrence of a film defect of the organic functional layer under the translucent electrically-conductive film can be suppressed while the occurrence of quenching is suppressed by disposing the translucent electrically-conductive film between the electrode and the organic light-emitting layer.

In an organic light-emitting device according to another mode, in the above-described configuration, the residual stress of the translucent electrically-conductive film is in a range of −200 [MPa] to +200 [MPa]. This can suppress the occurrence of a defect such as film separation of the organic functional layer more surely.

Furthermore, in an organic light-emitting device according to another mode, in the above-described configuration, the residual stress of the translucent electrically-conductive film is in a range of −200 [MPa] to +60 [MPa]. Also due to this, the organic light-emitting device is advantageous in further suppressing the occurrence of a defect such as film separation of the organic functional layer.

Moreover, in an organic light-emitting device according to another mode, in the above-described configuration, the distance from an interface in the organic light-emitting layer on the side of the first electrode to an interface in the second electrode on the side of the organic light-emitting layer and the distance from the interface in the organic light-emitting layer on the side of the first electrode to an interface in the first electrode on the side of the organic light-emitting layer correspond to the wavelength of light emitted from the organic light-emitting layer. High light emission efficiency can be obtained due to such cavity design.

Furthermore, in an organic light-emitting device according to another mode, in the above-described configuration, the film thickness of the translucent electrically-conductive film is larger than layer thickness of the organic functional layer. This can effectively suppress the occurrence of quenching while suppressing increase in optical loss and electrical loss.

Moreover, in an organic light-emitting device according to another mode, in the above-described configuration, an intermediate layer that contains a fluoride of an alkali metal or an alkaline earth metal and is in contact with the organic light-emitting layer is disposed between the organic light-emitting layer and the organic functional layer, and the organic functional layer is a layer containing an organic material obtained by being doped with an alkali metal or an alkaline earth metal. In the organic light-emitting device according to the present mode, because the intermediate layer is a layer containing a fluoride of an alkali metal or an alkaline earth metal, entry of impurities from the organic light-emitting layer side to the organic functional layer is blocked by this layer. Thus, favorable storage stability can be realized.

Furthermore, because the organic functional layer is an organic layer obtained by being doped with an alkali metal or an alkaline earth metal, it is possible to break the bond between the alkali metal or the alkaline earth metal and the fluorine in the fluoride of the alkali metal or the alkaline earth metal contained in the intermediate layer and release the alkali metal or the alkaline earth metal. Furthermore, the alkali metal or the alkaline earth metal has a low work function and high electron injection properties and thus allows sufficient electron supply to the organic light-emitting layer.

Therefore, the organic light-emitting device according to the present mode is advantageous in realizing favorable light emission characteristics.

Moreover, in an organic light-emitting device according to another mode, in the above-described configuration, the doping concentration of the alkali metal or the alkaline earth metal in the organic functional layer is equal to or higher than 20 [wt %] and is equal to or lower than 40 [wt %]. By setting the doping concentration in such a range, the electron supply capability in the organic functional layer can be enhanced and favorable light emission efficiency can be realized.

Furthermore, in an organic light-emitting device according to another mode, in the above-described configuration, a layer that contains an alkali metal or an alkaline earth metal and is in contact with the organic functional layer is disposed between the intermediate layer and the organic functional layer. Due to the interposing of the layer containing an alkali metal or an alkaline earth metal between the organic functional layer and the intermediate layer as above, the organic light-emitting device is advantageous in obtaining high electron injection properties.

In the configuration in which the layer containing an alkali metal or an alkaline earth metal is interposed, the doping concentration of the alkali metal or the alkaline earth metal in the organic functional layer is equal to or higher than 5 [wt %] and is equal to or lower than 40 [wt %]. By setting the doping concentration in such a range, the electron supply capability in the organic functional layer can be enhanced.

Furthermore, in an organic light-emitting device according to another mode, in the above-described configuration, a first intermediate layer that contains a fluoride of an alkali metal or an alkaline earth metal and is in contact with the organic light-emitting layer is disposed between the organic light-emitting layer and the organic functional layer, and a second intermediate layer that contains an alkali metal or an alkaline earth metal and is in contact with both layers of the first intermediate layer and the organic functional layer is disposed between the first intermediate layer and the organic functional layer. In the organic light-emitting device according to this mode, similarly to the case of doping the organic functional layer with an alkali metal or an alkaline earth metal, impurities from the organic light-emitting layer side to the organic functional layer can be effectively blocked and high electron injection capability can be obtained. Thus, in the organic light-emitting device according to the present mode, high light emission efficiency can be realized.

Moreover, in an organic light-emitting device according to another mode, in the above-described configuration, the second electrode is formed of Ag or MgAg or a layered body of them. If the configuration in which the second electrode is formed of Ag or MgAg or a layered body of them is employed as above, the organic light-emitting device is advantageous in intending improvement in the light emission efficiency by strong cavity design and improvement in the chromaticity.

Furthermore, in an organic light-emitting device according to another mode, in the above-described configuration, a major surface in the second electrode on the opposite side to the translucent electrically-conductive film is covered by a film having translucency. By covering the upper side of the second electrode by a film having translucency as above, protection of the second electrode formed of a metal thin film can be intended more surely.

Moreover, in an organic light-emitting device according to another mode, in the above-described configuration, the first electrode is also composed of a metal material or an alloy material and at least a major surface on the side of the organic light-emitting layer has light reflectivity. Due to this, a high-efficiency resonator structure can be formed between the first electrode and the second electrode in the device and the organic light-emitting device is advantageous in obtaining high light emission efficiency.

Furthermore, in an organic light-emitting device according to another mode, in the above-described configuration, the translucent electrically-conductive film is composed of indium tin oxide (ITO) or indium zinc oxide (IZO). This can suppress optical loss to a low level and also suppress electrical loss to a low level.

Moreover, in an organic light-emitting device according to another mode, in the above-described configuration, the translucent electrically-conductive film is composed of a material containing zinc oxide as a main component (zinc oxide-based material). If the translucent electrically-conductive film is composed of the zinc oxide-based material, increase in the resistance of the translucent electrically-conductive film can be intended compared with the case of employing the translucent electrically-conductive film composed of ITO or IZO. This is effective to suppress the occurrence of the dark dot.

Furthermore, in an organic light-emitting device according to another mode, in the above-described configuration, a material obtained by adding, to zinc oxide, at least one kind of element among tin (Sn), indium (In), gallium (Ga), magnesium (Mg), calcium (Ca), aluminum (Al), silicon (Si), thallium (TI), bismuth (Bi), and lead (Pb) can be employed as a concrete example of the zinc oxide-based material.

Moreover, in an organic light-emitting device according to another mode, in the above-described configuration, in the case of employing the translucent electrically-conductive film composed of the zinc oxide-based material, the resistivity thereof is equal to or higher than 1×102 [Ωcm] and is equal to or lower than 1×105 [Ωcm]. This can surely suppress the dark dot.

In the following, characteristics in the configurations of the above-described modes and operations and effects achieved from them will be described by using embodiments of several examples. However, the present invention is not limited by the following examples at all except for configurations deemed as essential characteristics thereof.

### Embodiment 1

### 1. Schematic Configuration of Organic EL Display Device 1

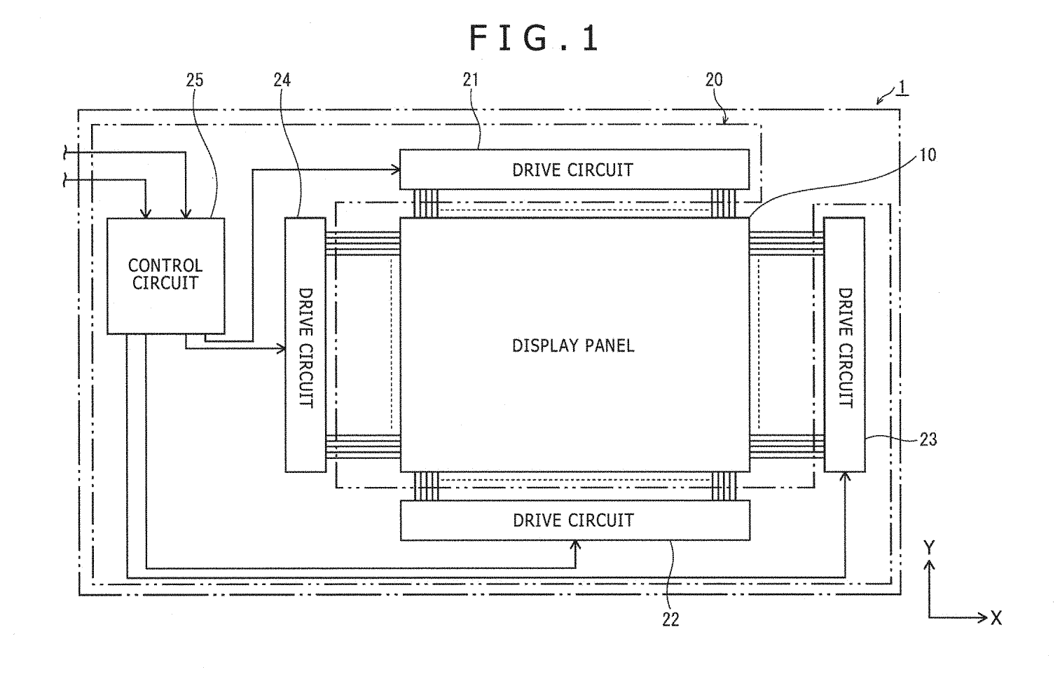

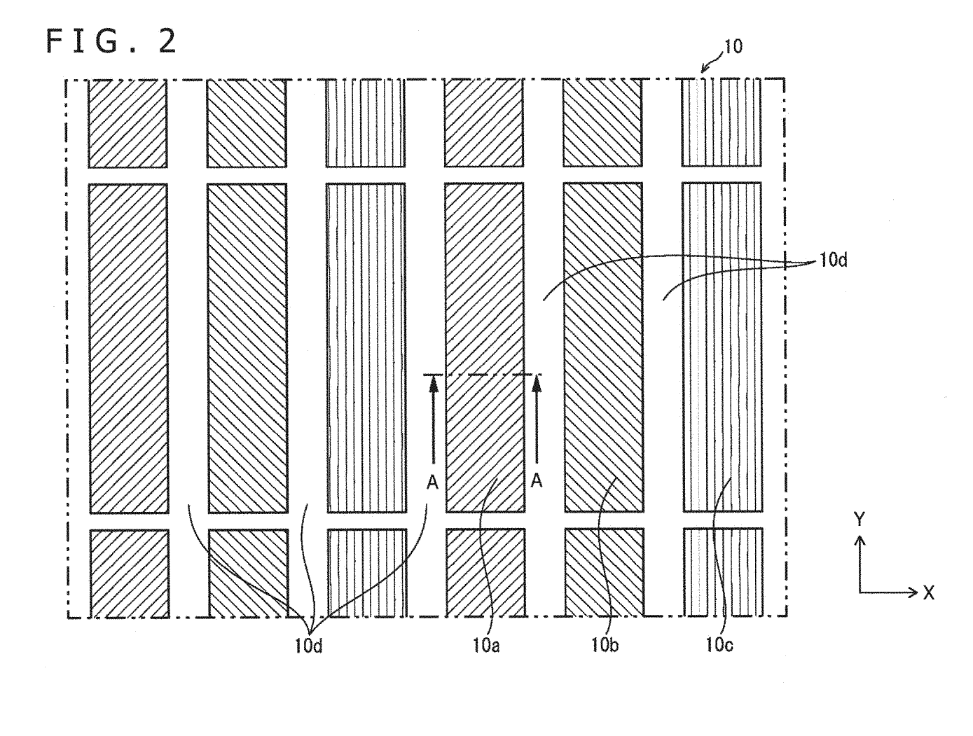

The schematic configuration of an organic EL display device 1 according to embodiment 1 of the present invention will be described by using FIG. 1 and FIG. 2.

As illustrated in FIG. 1, the organic EL display device 1 includes a display panel 10 and a drive-and-control circuit part 20 connected thereto. The display panel 10 is an organic EL panel that uses an electroluminescence phenomenon of an organic material and has plural pixels.

As illustrated in FIG. 2, each pixel is composed of a sub-pixel 10a that is a light-emitting part of red (R), a sub-pixel 10b that is a light-emitting part of green (G), and a sub-pixel 10c that is a light-emitting part of blue (B). In the present embodiment, the plural sub-pixels 10a to 10c are arranged in a matrix manner in the X-Y directions (two-dimensional arrangement). A non-light-emitting region 10d is disposed among the sub-pixels 10a to 10c adjacent to each other.

Referring back to FIG. 1, the drive-and-control circuit part 20 is composed of four drive circuits 21 to 24 and a control circuit 25.

The arrangement relationship between the display panel 10 and the drive-and-control circuit part 20 in the organic EL display device 1 is not limited to the form of FIG. 1.

Furthermore, the configuration of the pixels in the display panel 10 is not limited to a form composed of sub-pixels (light-emitting parts) of three colors of R, G, and B like that illustrated in FIG. 2, and one pixel may be composed of light-emitting parts of four or more colors.

### 2. Configuration of Display Panel 10

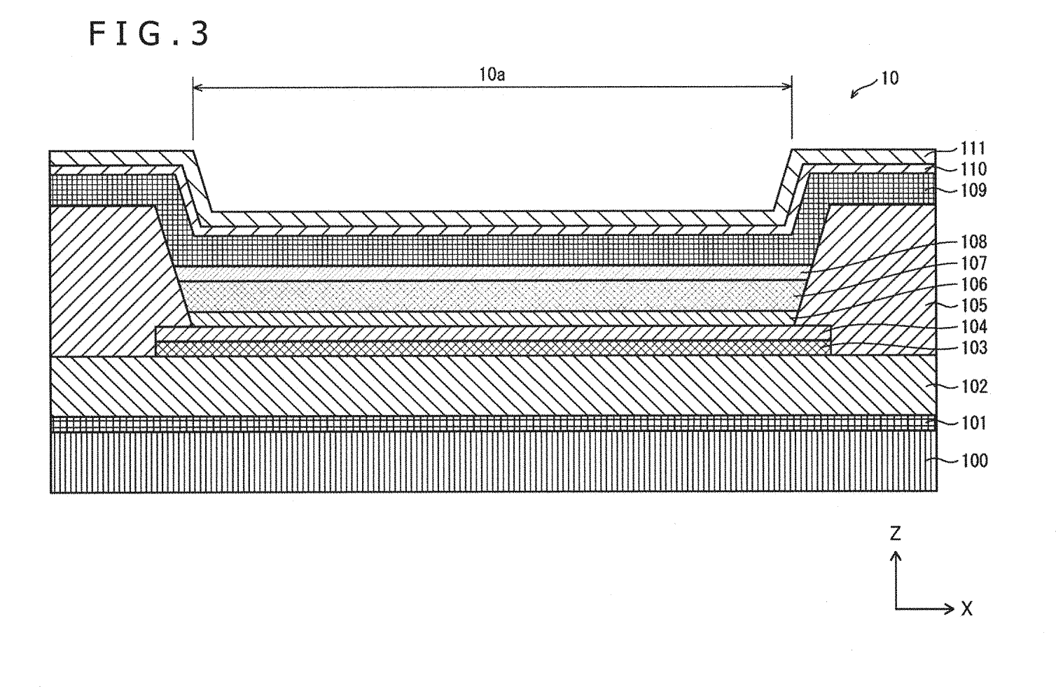

As illustrated in FIG. 3, in the display panel 10, a thin film transistor (TFT) layer 101 is formed on a substrate 100 and an insulating layer 102 is stacked thereon. The upper surface of the insulating layer 102 in the Z-axis direction is formed to be substantially flat.

Over the upper surface of the insulating layer 102 in the Z-axis direction, an anode 103 and a hole injection layer 104 marked off for each of the sub-pixels 10a to 10c are sequentially stacked and formed.

Next, a bank 105 is formed to cover the insulating layer 102 and both edges of the hole injection layer 104 in the X-axis direction. The bank 105 defines the aperture of each light-emitting region part in the sub-pixels 10a to 10c.

In each aperture defined by the bank 105, a hole transport layer 106, an organic light-emitting layer 107, and an electron transport layer 108 are stacked and formed sequentially from the lower side in the Z-axis direction. Among them, the electron transport layer 108 is equivalent to the organic functional layer.

A translucent electrically-conductive film 109, a cathode 110, and a sealing layer 111 are sequentially formed to cover the electron transport layer 108 and the top surface of the bank 105.

Here, a substrate is disposed over the sealing layer 111 with the intermediary of a resin layer. However, diagrammatic representation is omitted in FIG. 3.

The display panel 10 according to the present embodiment is a display panel of the top-emission type and light is emitted toward the upper side in the Z-axis direction through the cathode 110. Furthermore, in the display panel 10 according to the present embodiment, improvement in the light emission efficiency and improvement in the chromaticity are intended by employment of a secondary cavity.

### 3. Respective Constituent Materials of Display Panel 10

### (1) Substrate 100

The substrate 100 is formed by using a glass substrate, a quartz substrate, a silicon substrate, a metal substrate of molybdenum sulfide, copper, zinc, aluminum, stainless steel, magnesium, iron, nickel, gold, silver, or the like, a semiconductor substrate of gallium arsenic or the like, a plastic substrate, or the like for example.

As the plastic substrate, either a thermoplastic resin or a thermosetting resin may be used. For example, the following materials are cited and a layered body obtained by stacking one kind or two or more kinds among them can be used: polyolefin such as polyethylene, polypropylene, ethylene-propylene copolymer, and ethylene-vinyl acetate copolymer (EVA), cyclic polyolefin, modified-polyolefin, polyvinyl chloride, polyvinylidene chloride, polystyrene, polyimide, polyimide (PI), polyimide-imide, polycarbonate, poly-(4-methylpentene-1), ionomer, acrylic-based resin, polymethyl methacrylate, acrylic-styrene copolymer (AS resin), butadiene-styrene copolymer, polio copolymer (EVOH), polyester such as polyethylene terephthalate (PET), polybutylene terephthalate, polyethylene naphthalate (PEN), and polycyclohexane terephthalate (PCT), polyether, polyetherketone, polyethersulfone (PES), polyetherimide, polyacetal, polyphenylene oxide, modified-polyphenylene oxide, polyarylate, aromatic polyester (liquid crystal polymer), polytetrafluoroethylene, polyvinylidene difluoride, other fluorine-based resins, various kinds of thermoplastic elastomers such as styrene series, polyolefin series, polyvinyl chloride series, polyurethane series, fluorine rubber series, and chlorinated polyethylene series, epoxy resin, phenolic resin, urea resin, melamine resin, unsaturated polyester, silicone resin, polyurethane, and so forth, or copolymers, blends, polymer alloys, and so forth composed mainly of them.

### (2) TFT Layer 101

### (i) Gate Electrode

As the constituent material of a gate electrode, the material is configured to contain copper (Cu) for example. For example, a layered body of a layer composed of copper (Cu) and a layer composed of molybdenum (Mo) can be employed.

However, the configuration of the gate electrode is not limited thereto. For example, it is also possible to employ a Cu single layer, a layered body of Cu/W, or the like, and it is also possible to employ the following materials.

As other materials that can be employed, the following materials are cited: metals such as chromium (Cr), aluminum (Al), tantalum (Ta), niobium (Nb), silver (Ag), gold (Au), platinum (Pt), palladium (Pd), indium (In), nickel (Ni), and neodymium (Nd) or alloys of them, or electrically-conductive metal oxides such as zinc oxide, tin oxide, indium oxide, and gallium oxide or electrically-conductive metal composite oxides such as indium tin oxide (ITO), indium zinc oxide (IZO), aluminum zinc oxide (AZO), and gallium zinc oxide (GZO), or electrically-conductive polymers such as polyaniline, polypyrrole, polythiophene, and polyacetylene or materials obtained by adding, to them, a dopant of an acid such as hydrochloric acid, sulfuric acid, or sulfonic acid, a Lewis acid such as phosphorus hexafluoride, arsenic pentafluoride, or iron chloride, a halogen atom such as iodine, a metal atom such as sodium or potassium, or the like, or electrically-conductive composite materials in which carbon black or metal particles are dispersed, or the like. Furthermore, a polymer mixture containing metal fine particles and electrically-conductive particles like graphite may be used. It is also possible to use them with one kind or two or more kinds combined.

### (ii) Gate Insulating Layer

As the configuration of a gate insulating layer, a layered body of silicon oxide (SiO) and silicon nitride (SiN) can be employed for example. However, the configuration of the gate insulating layer is not limited thereto. As the constituent material of the gate insulating layer, for example either a publicly-known organic material or inorganic material can be used as long as it is a material having electrical insulation properties.

As the organic material, for example acrylic-based resin, phenol-based resin, fluorine-based resin, epoxy-based resin, imide-based resin, novolac-based resin, or the like can be used to form the gate insulating layer.

Furthermore, as the inorganic material, for example the following materials are cited: metal oxides such as silicon oxide, aluminum oxide, tantalum oxide, zirconium oxide, cerium oxide, zinc oxide, and cobalt oxide, metal nitrides such as silicon nitride, aluminum nitride, zirconium nitride, cerium nitride, zinc nitride, cobalt nitride, titanium nitride, and tantalum nitride, and metal composite oxides such as barium strontium titanate and lead zirconium titanate. It is possible to use them with one kind or two or more kinds combined.

Moreover, a layer whose surface is treated by a surface treatment agent (ODTS OTS HMDS βPTS) or the like is also included.

(iii) Channel Layer

As the configuration of a channel layer, a layer composed of amorphous indium gallium zinc oxide (IGZO) can be employed. The constituent material of the channel layer is not limited thereto and an oxide semiconductor containing at least one kind selected from indium (In), gallium (Ga), and zinc (Zn) can be employed.

Furthermore, the layer thickness of the channel layer can be set in a range of 20 [nm] to 200 [nm] for example. The layer thickness does not need to be identical in all channel layers formed in the display panel 10 and it is also possible to set the layer thickness in such a manner that part of the layer thickness is different.

### (iv) Channel Protective Layer

As the configuration of a channel protective layer, a layer composed of silicon oxide (SiO) can be employed. However, the constituent material of the channel protective material is not limited thereto. For example, silicon oxynitride (SiON), silicon nitride (SiN), or aluminum oxide (AlOx) can be used. Furthermore, it is also possible to form the channel protective layer by stacking plural layers using the above-described materials.

Furthermore, the layer thickness of the channel protective layer can be set in a range of 50 [nm] to 500 [nm] for example.

### (v) Source Electrode and Drain Electrode

As the configuration of source electrode and drain electrode, a layered body of copper manganese (CuMn) and molybdenum (Mo) can be employed for example.

### (vi) Interlayer Insulating Layer

As the configuration of an interlayer insulating layer, a layer composed of silicon oxide (SiO) can be employed for example.

(vii) Upper Electrode

As the configuration of an upper electrode, a layered body of copper manganese (CuMn) and molybdenum (Mo) can be employed similarly to the source electrode and drain electrode and so forth.

(viii) Passivation Layer

As the configuration of a passivation layer, a layer composed of silicon nitride (SiN) can be employed.

If the channel layer composed of an oxide semiconductor is employed, for the purpose of suppressing reduction thereof, it is also possible to employ the passivation layer with a configuration in which silicon oxide (SiO) and silicon nitride (SiN) are stacked from the channel layer side.

### (3) Insulating Layer 102

The insulating layer 102 is formed by using an organic compound such as polyimide, polyamide, or an acrylic-based resin material for example. Here, it is preferable for the insulating layer 102 to have resistance against the organic solvent.

Furthermore, the insulating layer 102 is often subjected to etching treatment, baking treatment, and so forth in a manufacturing step. Thus, it is preferable for the insulating layer 102 to be formed by using a material having high resistance with which excessive deformation and alteration are not caused in response to these kinds of treatment.

### (4) Anode 103

The anode 103 is composed of a metal material containing silver (Ag) or aluminum (Al). In the case of the display panel 10 according to the present embodiment as a top-emission type, it is preferable that the surface part of the anode 103 have high reflectivity.

Regarding the anode 103, not only a single layer structure composed of a metal material like the above-described structure but also a layered body of a metal layer and a transparent electrically-conductive layer can be employed. As the constituent material of the transparent electrically-conductive layer, indium tin oxide (ITO), indium zinc oxide (IZO), or the like can be used for example.

### (5) Hole Injection Layer 104

The hole injection layer 104 is a layer composed of an oxide of silver (Ag), molybdenum (Mo), chromium (Cr), vanadium (V), tungsten (W), nickel (Ni), iridium (Ir), or the like or an electrically-conductive polymer material such as PEDOT/PSS (mixture of polythiophene and polystyrene sulfonate) for example.

If a metal oxide is used as the constituent material of the hole injection layer 104, the hole injection layer 104 has a function of stably injecting holes or assisting generation of holes to inject the holes into the organic light-emitting layer 107 and has a high work function compared with the case of using an electrically-conductive polymer material such as PEDOT/PSS.

Here, if the hole injection layer 104 is composed of a transition metal oxide, the transition metal oxide takes plural oxidation numbers and thus can take plural levels due to this. As a result, the hole injection becomes easy and the drive voltage can be decreased. In particular, using tungsten oxide (WOX) is preferable in terms of having a function of stably injecting holes and assisting generation of holes.

### (6) Bank 105

The bank 105 is formed by using an organic material such as a resin and has insulation properties. As examples of the organic material used for the formation of the bank 105, acrylic-based resin, polyimide-based resin, novolac-type phenolic resin, and so forth are cited. It is also possible to subject the surface of the bank 105 to fluorine treatment in order to cause the surface to have water repellency.

Moreover, regarding the structure of the bank 105, not only a one-layer structure like that illustrated in FIG. 3 but also a multilayer structure of two or more layers can be employed. In this case, it is also possible to combine the above-described materials for each layer and it is also possible to use an inorganic material and an organic material for each layer.

### (7) Hole Transport Layer 106

The hole transport layer 106 is formed by using a polymer compound that does not have a hydrophilic group. For example, a material that is a polymer compound such as polyfluorene or a derivative thereof or poly(aryl amine) or a derivative thereof and does not have a hydrophilic group, or the like, can be used.

### (8) Organic Light-Emitting Layer 107

The organic light-emitting layer 107 has a function of emitting light through generation of the excited state due to injection and recombination of holes and electrons. It is necessary to use a luminescent organic material that can be deposited by using a wet printing method as the material used for the formation of the organic light-emitting layer 107.

Specifically, for example, it is preferable for the organic light-emitting layer 107 to be formed of the following fluorescent substances described in a Patent Publication (Japan• JP 1993-163488A): oxynoid compound, perylene compound, coumarin compound, azacoumarin compound, oxazole compound, oxadiazole compound, perinone compound, pyrrolopyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylenepyran compound, dicyanomethylenethiopyran compound, fluorescein compound, pyrylium compound, thiapyrylium compound, selenapyrylium compound, telluropyrylium compound, aromatic aldadiene compound, oligophenylene compound, thioxanthene compound, anthracene compound, cyanine compound, acridine compound, metal complex of 8-hydroxyquinoline compound, metal complex of 2-bipyridine compound, complex of Schiff base and group III metal, oxine metal complex, and rare earth complex.

### (9) Electron Transport Layer 108

The electron transport layer 108 has a function of transporting electrons injected from the cathode 110 to the organic light-emitting layer 107 and is formed by using an oxadiazole derivative (OXD), a triazole derivative (TAZ), a phenanthroline derivative (BCP, Bphen), or the like for example.

### (10) Translucent Electrically-Conductive Film 109

The translucent electrically-conductive film 109 is composed of a material that is composed mainly of indium tin oxide (ITO) or indium zinc oxide (IZO) or zinc oxide (ZnO) and is obtained by causing an additive to be contained therein (hereinafter, described as “zinc oxide-based material”). The film thickness of the translucent electrically-conductive film 109 is set to 60 [nm] or larger. Regarding the film thickness of the translucent electrically-conductive film 109, it is more preferable to set the film thickness to 100 [nm] or larger. Here, as concrete examples of the additive in the zinc oxide-based material, at least one kind of element among tin (Sn), indium (In), gallium (Ga), magnesium (Mg), calcium (Ca), aluminum (Al), silicon (Si), thallium (TI), bismuth (Bi), and lead (Pb) is cited for example.

Furthermore, regarding the translucent electrically-conductive film 109, it is preferable that the transmittance of light be 80[%] or higher. The transmittance of light here is values when the wavelength is 450 [nm] and in the vicinity of it (for example, ±10 [nm]) and is 520 [nm] and in the vicinity of it (for example, ±10 [nm]) and is 620 [nm] and in the vicinity of it (for example, ±10 [nm]).

Moreover, in the translucent electrically-conductive film 109, the residual stress is set in a range of −400 [MPa] to +400 [MPa], more preferably in a range of −200 [MPa] to +200 [MPa], and further preferably in a range of −200 [MPa] to +60 [MPa].

Here, it has been confirmed that the residual stress indicates a value of approximately −170 [MPa] (for example, −180 [MPa] to −160 [MPa]) in at least one direction of the X-direction and the Y-direction (see FIG. 2) in the case of forming the translucent electrically-conductive film 109 by using the zinc oxide-based material.

Although the method for controlling the residual stress of the translucent electrically-conductive film 109 will be described later, the control is carried out based on prescription of the film deposition condition.

Moreover, in the case of forming the translucent electrically-conductive film 109 by using the zinc oxide-based material, increase in the resistance can be intended compared with the case of forming the translucent electrically-conductive film 109 by using ITO or IZO. Thus, using the zinc oxide-based material is advantageous in intending suppression of the dark dot. Specifically, the resistivity of the zinc oxide-based material is 1×102 [Ωcm] to 1×105 [Ωcm] whereas the resistivity of ITO and IZO is 5×10−4 [Ωcm]. By intending increase in the resistance as above, suppression of the dark dot can be intended. In terms of such suppression of the dark dot, it is preferable that AZO (material obtained by doping zinc oxide with aluminum), GZO (material obtained by doping zinc oxide with gallium), and so forth used as the material of a transparent electrically-conductive film be not included in the “zinc oxide-based material” in the present disclosure.

### (11) Cathode 110

The cathode 110 is formed of a metal thin film for example. As the metal material used, silver (Ag), an alloy of silver and magnesium (MgAg), or the like is employed. Note that regarding the cathode 110, not only a single-layer structure but also a configuration obtained by stacking plural layers can be employed. Furthermore, in the cathode 110 in the present embodiment, the film thickness is 30 [nm] for example. The purpose of employing a metal thin film also regarding the cathode 110, which is on the light extraction side, as above is to intend improvement in the light emission efficiency by a strong cavity and improvement in the chromaticity.

### (12) Sealing Layer 111

The sealing layer 111 has a function of suppressing exposure of organic layers such as the organic light-emitting layer 107 to water and exposure to air and is formed by using a material such as silicon nitride (SiN) or silicon oxynitride (SiON) for example. Furthermore, a sealing resin layer composed of a resin material such as an acrylic resin or a silicone resin may be provided on the layer formed by using a material such as silicon nitride (SiN) or silicon oxynitride (SiON).

Moreover, regarding the sealing layer 111, not only a single-layer structure but also a configuration obtained by stacking plural layers can be employed. For example, it is also possible to employ a configuration in which an SiO layer and an SiN layer (or SiON layer) are sequentially stacked from the side of the cathode 110.

In the case of the display panel 10 according to the present embodiment as a top-emission type, the sealing layer 111 needs to be formed of a light-transmissive material.

In FIG. 3, the sub-pixel 10a is employed as the representative and the configuration thereof is described. However, also regarding the other sub-pixels 10b and 10c, basically a similar configuration is employed.

### 4. Consideration Concerning Film Thickness of Each Constituent Layer

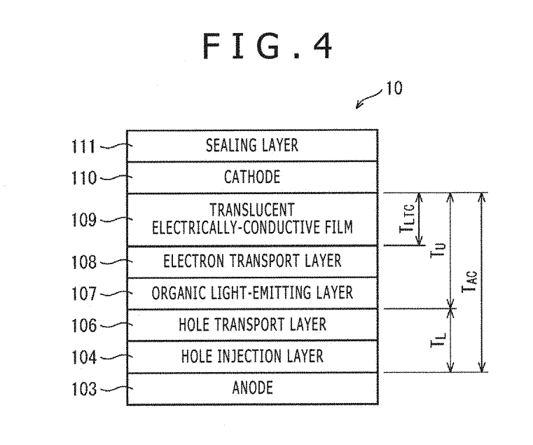

A result of consideration concerning the film thickness of the constituent layers configuring the display panel 10 will be described by using FIG. 4 to FIG. 8.

First, in FIG. 4, a diagram in which part of the display panel 10 is made schematic is illustrated.

As illustrated in FIG. 4, the distance between the upper-side interface of the anode 103 (interface on the side of the hole injection layer 104) and the lower-side interface of the cathode 110 (interface on the side of the translucent electrically-conductive film 109) is defined as TAC. Furthermore, the distance between the upper-side interface of the anode 103 and the lower-side interface of the organic light-emitting layer 107 (interface on the side of the hole injection layer 104) is defined as TL.

The distance between the lower-side interface of the organic light-emitting layer 107 and the lower-side interface of the cathode 110 is defined as TU. Moreover, the distance between the lower-side interface of the translucent electrically-conductive film 109 (interface on the side of the electron transport layer 108) and the lower-side interface of the cathode 110, in other words, the film thickness of the translucent electrically-conductive film 109, is defined as TLTC.

First, in the display panel 10 according to the present embodiment, optical design with use of a secondary cavity is carried out. For this purpose, TAC≈195 [nm] (for example, TAC=195 [nm]±10 [nm]) is set.

Next, in terms of suppressing the occurrence of cathode quenching, TU≈150 [nm] (for example, TU=150 [nm]±10 [nm]) is set. Furthermore, TL is prescribed in consideration the optimization in the optical design and TL≈45 [nm] (for example, TL=45 [nm]±10 [nm]) is set in the present embodiment.

Furthermore, TLTC=60 [nm] is set in terms of suppression of the occurrence of cathode quenching and in terms of reduction in optical loss and electrical loss. Note that it suffices for TLTC to be set to 60 [nm] or larger in terms of suppression of the occurrence of cathode quenching. For this reason, TLTC in the present embodiment is permitted even when having variation in the positive direction (thicker direction) with respect to a described numerical value (this is the same in the present specification). Furthermore, it is preferable for TLTC to be set to 100 [nm] or larger in terms of suppression of the occurrence of cathode quenching.

### (i) Suppression of Occurrence of Cathode Quenching

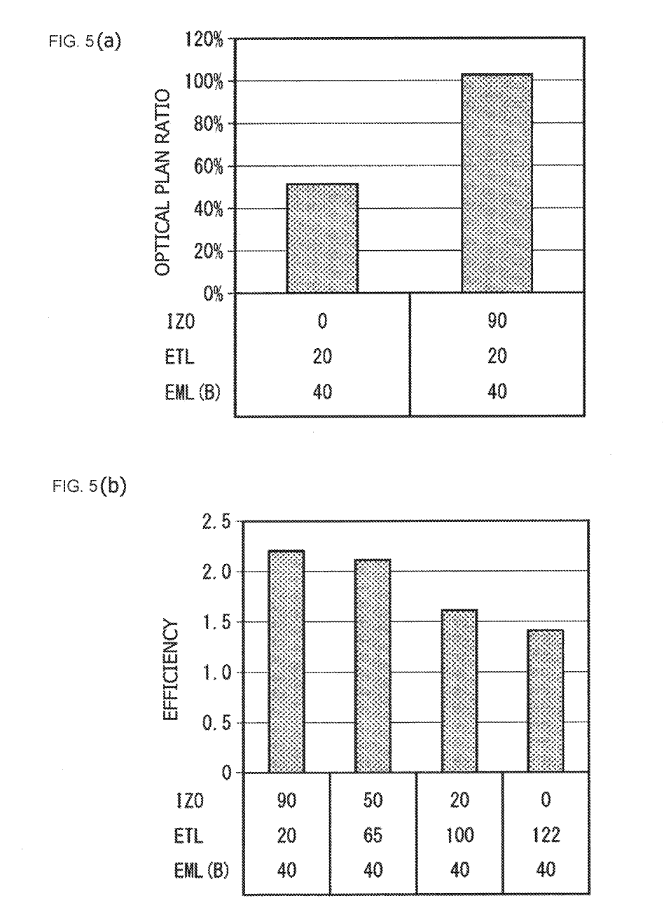

As illustrated in FIG. 5(a), if the translucent electrically-conductive film (IZO) is not stacked on the electron transport layer (ETL), the optical plan ratio becomes approximately 50% and the occurrence of cathode quenching is observed.

In contrast thereto, it turns out that the optical plan ratio becomes approximately 100% and the occurrence of cathode quenching is suppressed if the translucent electrically-conductive film (IZO) is stacked on the electron transport layer (ETL). Thus, in consideration concerning manufacturing variation and so forth, TLTC=60 [nm] and TU≈150 [nm] (for example, TU=150 [nm]±10 [nm]) are set. TLTC here is also permitted even when having variation in the positive direction with respect to a described numerical value as described above.

### (ii) Optical Loss and Electrical Loss

As illustrated in FIG. 5(b), measurement of the light emission efficiency was carried out with change in the film thickness ratio between the electron transport layer (ETL) and the translucent electrically-conductive film (IZO). From the result illustrated in FIG. 5(b), high efficiency is indicated until the film thickness ratio between the translucent electrically-conductive film (IZO) and the electron transport layer (ETL) becomes equivalent. However, the efficiency when the translucent electrically-conductive film (IZO) was 20 [nm] or 0 [nm] (case in which the translucent electrically-conductive film was absent) greatly decreased.

Therefore, in suppressing the occurrence of cathode quenching, not increasing the film thickness of the electron transport layer but interposing the translucent electrically-conductive film is important in terms of suppressing optical loss and electrical loss.

(iii) Cavity Design

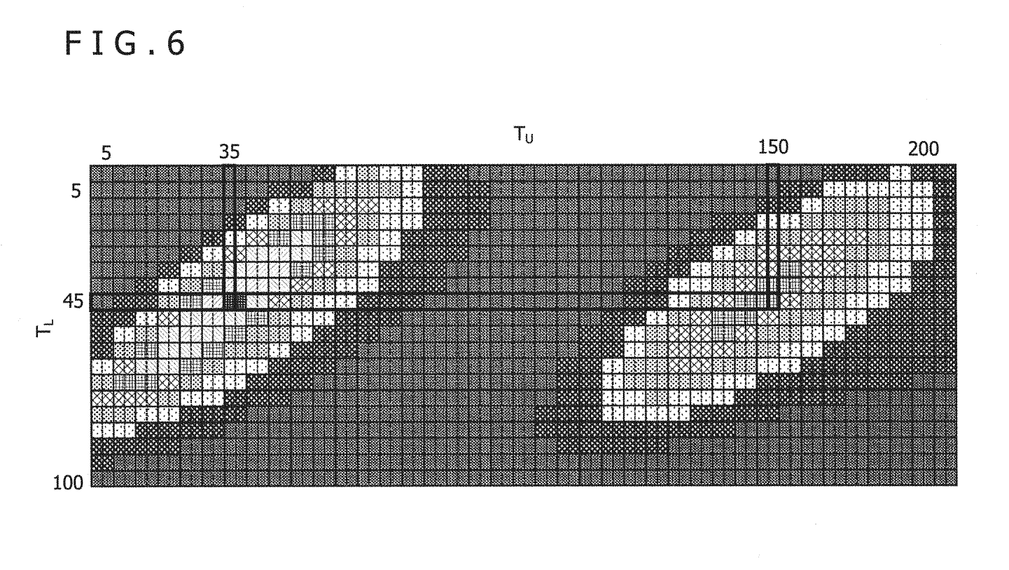

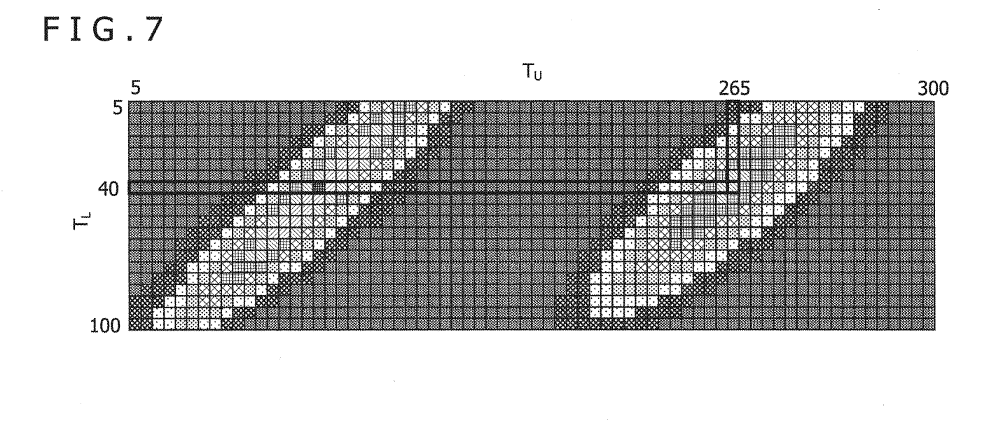

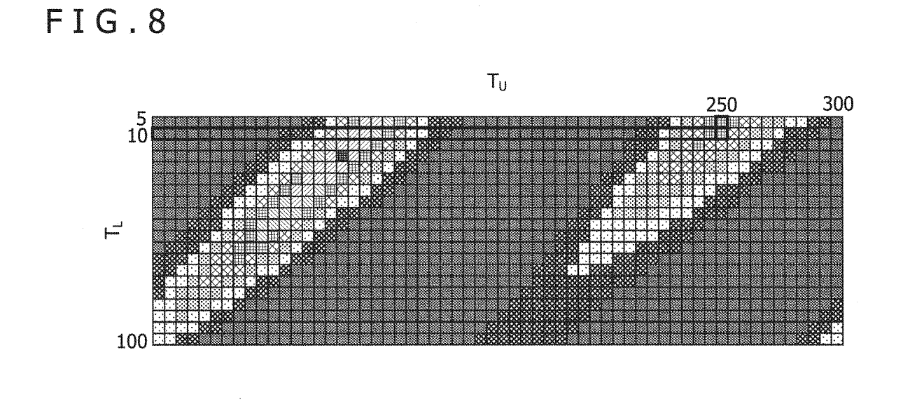

Results of studies concerning optimization of the optical path length in cavity design are illustrated in FIG. 6 to FIG. 8. In FIG. 6, the result of simulation of the luminance of light emitted with mutual change in TU and TL in the sub-pixel of blue (B) is represented. In FIG. 7, the result of simulation of the luminance of light emitted with mutual change in TU and TL in the sub-pixel of red (R) is represented. In FIG. 8, the result of simulation of the luminance of light emitted with mutual change in TU and TL in the sub-pixel of green (G) is represented.

The island-shaped part on the left side in each of FIG. 6 to FIG. 8 is the primary cavity and the island-shaped part on the right side is the secondary cavity. In the present embodiment, optical design with use of the secondary cavity is carried out. Therefore, the island-shaped part on the right side in FIG. 6 will be mainly described. The luminance becomes higher as the position moves toward the inside from the peripheral part in each island-shaped part in each of FIG. 6 to FIG. 8.

### <<B Sub-Pixel>>

When the island-shaped part on the right side in FIG. 6 is seen, the luminance is high when TU and TL, and TAC which is the sum of TU and TL, are in the following ranges.

137.5 [nm]≦TU≦155.0 [nm] [Expression 1]

35.0 [nm]≦TL≦55.0 [nm] [Expression 2]

182.5 [nm]≦TAC≦200.0 [nm] [Expression 3]

### <<R Sub-Pixel>>

Similarly, when the island-shaped part on the right side in FIG. 7 is seen, the luminance is high when TU and TL, and TAC which is the sum of TU and TL, are in the following ranges.

255.0 [nm]≦TU≦275.0 [nm] [Expression 4]

30.0 [nm]≦TL≦50.0 [nm] [Expression 5]

285.0 [nm]≦TAC≦325.0 [nm] [Expression 6]

### <<G Sub-Pixel>>

Similarly, when the island-shaped part on the right side in FIG. 8 is seen, the luminance is high when TU and TL, and TAC which is the sum of TU and TL, are in the following ranges.

240.0 [nm]≦TU≦260.0 [nm] [Expression 7]

5.0 [nm]≦TL≦20.0 [nm] [Expression 8]

245.0 [nm]≦TAC≦280.0 [nm] [Expression 9]

### 5. Consideration Concerning Residual Stress of Translucent Electrically-Conductive Film 109

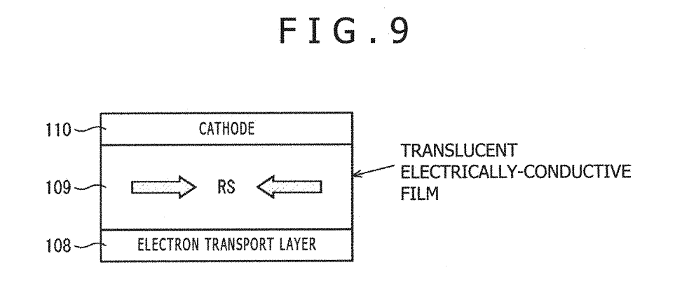

As described above, a causal relationship exists between the residual stress of the translucent electrically-conductive film 109 and a film defect of the electron transport layer 108. A result of consideration concerning this will be described by using FIG. 9 and [Table 1] and [Table 2] indicated below. FIG. 9 is a diagram in which the electron transport layer 108, the translucent electrically-conductive film 109, and the cathode 110 are extracted and schematically represented. Here, the residual stress in the translucent electrically-conductive film 109 is represented as “RS” and stress in the shrinkage direction is deemed with “−” and stress in the extension direction is deemed with “+.”

The result of measurement of the residual stress RS of the translucent electrically-conductive film 109 and the result of checking of whether or not a film defect of the electron transport layer 108 occurs and the degree thereof are represented in [Table 1] and [Table 2].

TABLE 1

| | Residual stress | Status of occurrence |
|---|---|---|
| | of translucent | of film defect |
| | electrically-conductive | of electron transport |
| | film (MPa) | layer (X-direction) |
| 1 | +58.5 | 1 |
| 2 | −20.5 | 1 |
| 3 | −151.5 | 1 |
| 4 | −172.5 | 1 |
| 5 | −200.0 | 1 |
| 6 | −358.5 | 2 |
| 7 | −420.5 | 3 |
| 8 | −503.5 | 3 |
| 9 | −607.0 | 4 |
| 10 | −676.0 | 4 |
| 11 | −834.5 | 4 |

TABLE 2

| | | Status of occurrence of |
|---|---|---|
| | Residual stress of translucent | film defect of electron |
| | electrically-conductive film (MPa) | transport layer (Y-direction) |
| 1 | +58.5 | 1 |
| 2 | +20.5 | 1 |
| 3 | −107.0 | 1 |
| 4 | −131.0 | 1 |
| 5 | −151.5 | 1 |
| 6 | −283.0 | 2 |
| 7 | −320.5 | 2 |
| 8 | −393.0 | 2 |
| 9 | −462.0 | 3 |
| 10 | −510.5 | 3 |
| 11 | −627.5 | 4 |

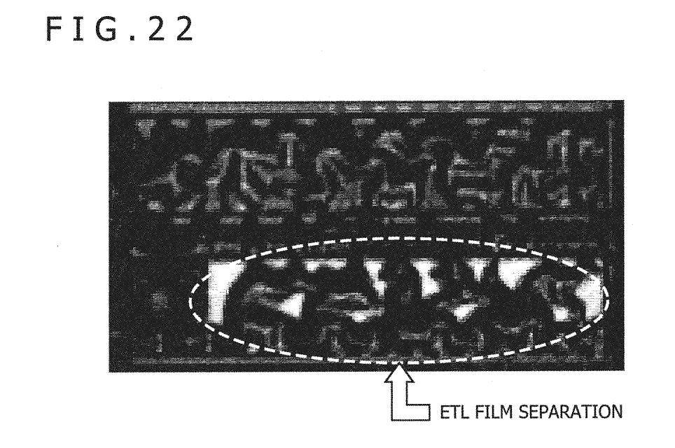

Regarding “Status of occurrence of film defect of electron transport layer” in [Table 1] and [Table 2], a layer that hardly involves the occurrence of a film defect is represented as “1” and a layer that involves the occurrence of a defect associated with film separation like that illustrated in FIG. 22 is represented as “4.” Layers in an intermediate status between them are represented as “2” and “3.”

Note that [Table 1] indicates the measurement result in the “X-direction” in FIG. 2 and so forth and [Table 2] indicates the measurement result in the “Y-direction.”

As indicated in [Table 1] and [Table 2], a film defect of the electron transport layer 108 was not observed in samples in which the residual stress RS of the translucent electrically-conductive film 109 was −200 [MPa] to +60 [MPa], specifically samples 1 to 5.

Next, in the X-direction of sample 6 indicated in [Table 1] and the Y-direction of samples 6 to 8 indicated in [Table 2], the residual stress RS was in a range of −400 [MPa] to −200 [MPa] and a slight film defect was observed in the electron transport layer 108. However, the defect was not at such a level as to become a problem as the organic light-emitting device.

In samples in which the residual stress RS was lower than −400 [MPa], specifically in the X-direction of samples 7 to 11 indicated in [Table 1] and the Y-direction of samples 9 to 11 indicated in [Table 2], a film defect occurred in the electron transport layer 108 and it is considered that employment of the electron transport layer 108 as the organic light-emitting device will be difficult.

From the above results, the inventors consider that the residual stress RS of the translucent electrically-conductive film 109 needs to be set in a range of −400 [MPa] to +400 [MPa] to suppress the occurrence of a film defect of the electron transport layer 108. It is more preferable to set the residual stress RS of the translucent electrically-conductive film 109 in a range of −200 [MPa] to +200 [MPa] and it is further preferable to set the residual stress RS in a range of −200 [MPa] to +60 [MPa].

### 6. Effects

In the display panel 10 according to the present embodiment, by inserting the translucent electrically-conductive film 109 whose film thickness is equal to or larger than 60 [nm] between the electron transport layer 108 as the organic functional layer and the cathode 110, the gap between the organic light-emitting layer 107 and the cathode 110 can be ensured and the occurrence of cathode quenching can be suppressed.

Furthermore, in this display panel 10, the occurrence of a film defect such as film separation of the electron transport layer 108 can be suppressed by setting the residual stress RS of the translucent electrically-conductive film 109 in a range of −400 [MPa] to +400 [MPa].

Therefore, in the display panel 10 according to the present embodiment, the occurrence of a film defect of the electron transport layer 108 under the translucent electrically-conductive film 109 can be suppressed while the occurrence of cathode quenching is suppressed by disposing the translucent electrically-conductive film 109 between the cathode 110 and the organic light-emitting layer 107, more specifically between the cathode 110 and the electron transport layer 108.

In the present consideration, the translucent electrically-conductive film 109 formed by using IZO is employed. However, it has been confirmed that similar results are obtained also regarding the case in which the translucent electrically-conductive film 109 is formed by using ITO and the case in which the translucent electrically-conductive film 109 is formed by using the zinc oxide-based material.

Specifically, in [Table 2], a sample that exhibits the residual stress RS at −170 [MPa] and in the neighborhood of it does not exist. However, it has been confirmed that, also in the Y-direction, a film defect of the electron transport layer 108 hardly occurs as with the result of the X-direction of sample 4 (see [Table 1]) when the residual stress RS is approximately −170 [MPa] (−180 [MPa] to −160 [MPa]). Thus, also when the translucent electrically-conductive film 109 is formed by using the zinc oxide-based material (material containing zinc oxide as the main component), prescribing the residual stress RS thereof in the above-described range causes a film defect of the electron transport layer 108 to hardly occur.

### 7. Manufacturing Method of Display Panel 10

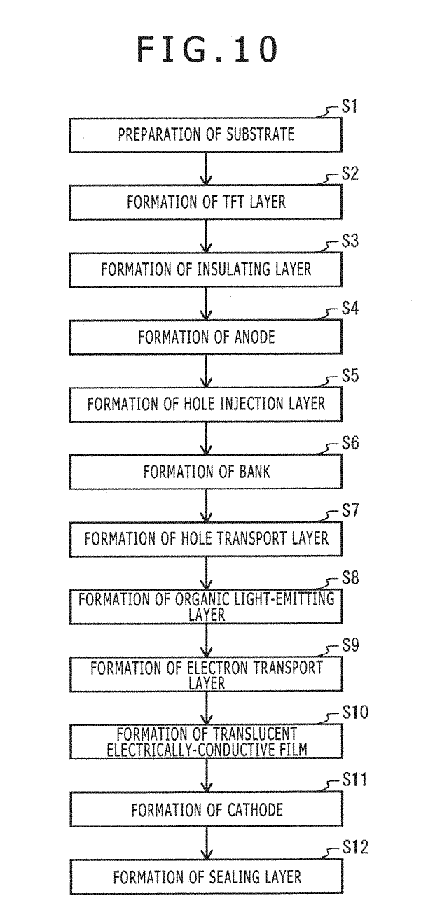

The outline of the manufacturing method of the display panel 10 will be described by using FIG. 10.

As illustrated in FIG. 10, first the substrate 100 is prepared (step S1). Then, the TFT layer 101 and the insulating layer (planarizing layer) 102 are sequentially stacked and formed over one major surface of the substrate 100 (major surface on the upper side in the Z-axis direction in FIG. 3) (steps S2 and S3). Although diagrammatic representation and description regarding details of the TFT layer 101 are omitted here, the TFT layer 101 is formed by configuring three electrodes of gate, source, and drain, a gate insulating layer, a channel layer, a channel protective layer, a passivation layer, and so forth by using the above-described materials.

Next, a metal film (for example, Al alloy film) is formed to cover the whole surface of the insulating layer 102 and then a film for the hole injection layer 104 (for example, WOX film) is formed to cover the whole surface of the metal film. Here, for example, a vacuum evaporation method or a sputtering method can be used for the deposition of the metal film, and a reactive sputtering method can be used for the deposition of the film for the hole injection layer 104. Photolithography and etching are used for the layered body of the metal film and the film for the hole injection layer 104 to carry out patterning of this layered body, so that formation of the anode 103 and the hole injection layer (HIL) 104 is completed (steps S4 and S5).

Next, a material film for forming the bank 105 is stacked and formed to cover the surface of the hole injection layer 104 and the exposed surface of the insulating layer 102. The material film for the bank 105 can be formed by using a spin-coating method or the like, for example. Then, the material film for the bank 105 is exposed and developed and thereby the bank 105 that defines the aperture is completed (step S6). The exposure and development are carried out until the surface of the hole injection layer 104 is exposed at the bottom part of the aperture.

Next, the hole transport layer 106, the organic light-emitting layer 107, and the electron transport layer 108 are sequentially formed for the aperture defined by the bank 105 (steps S7 to S9). The formation of these layers 106 to 108 is carried out by dropping the respective inks by using ink-jet apparatus and drying the inks, for example.

Subsequently, the translucent electrically-conductive film 109, the cathode 110, and the sealing layer 111 are sequentially stacked and formed to continuously cover the surface of the electron transport layer 108 and the top surface part of the bank 105 (steps S10 to S12). The formation of these layers 109 to 111 is carried out by using a sputtering method, for example.

At last, although diagrammatic representation is omitted, a color filter (CF) panel is stuck over the sealing layer 111 with the intermediary of a resin layer and thereby the display panel 10 is completed. It is also possible to employ a configuration in which a translucent substrate is stuck instead of the CF panel. That is, omission of the color filter is also possible.

### 8. Film Deposition Condition of Translucent Electrically-Conductive Film 109

The present embodiment is characterized in that the residual stress RS of the translucent electrically-conductive film 109 is suppressed in the above-described range in order to suppress the occurrence of a film defect of the electron transport layer 108. Thus, the film deposition condition of the translucent electrically-conductive film 109 is prescribed as follows.

Constituent material; IZO (indium zinc oxide)
Film deposition method; sputtering method
Total pressure; 0.6 [Pa]
Ar; 200 [sccm]
O2; 5 [sccm]
The respective flow rates of Ar and O2 are numerical values at 25 [° C.] and 100 [kPa].

By carrying out film deposition under the above-described condition, the residual stress in both directions of the X-direction and the Y-direction can be set to substantially “0.”

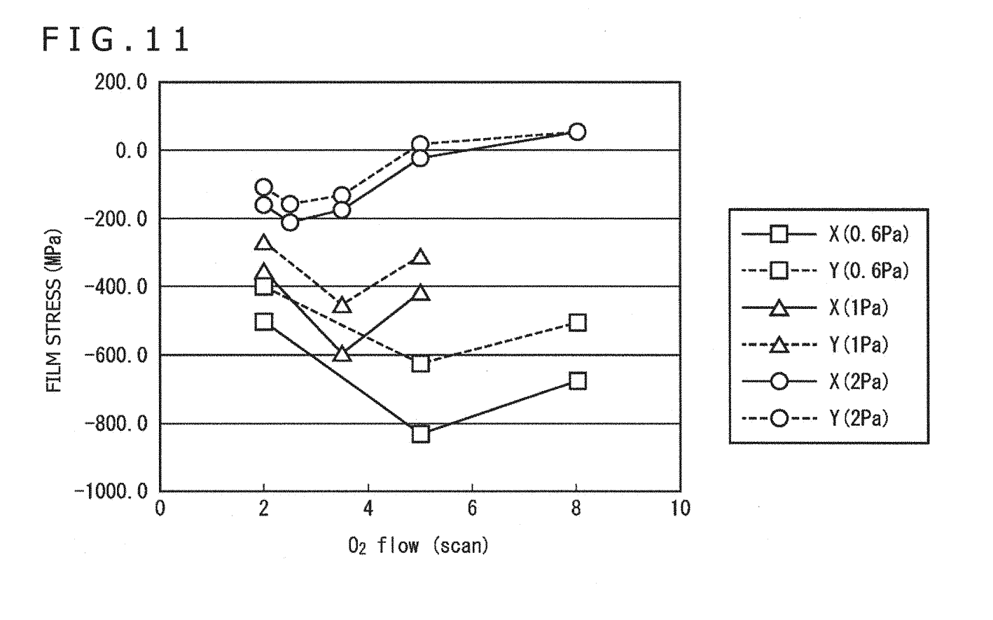

The relationship between the film deposition condition and the residual stress of the translucent electrically-conductive film 109 will be described by using FIG. 11. In FIG. 11, indium zinc oxide (IZO) is employed as one example of the constituent material. However, in the case of using another translucent electrically-conductive material such as indium tin oxide (ITO) or the zinc oxide-based material (material containing zinc oxide as the main component), the relationship between the film deposition condition and the residual stress can be obtained on each material basis.

As illustrated in FIG. 11, it turns out that the absolute value of the residual stress becomes larger as the total pressure relating to the film deposition is decreased to 2.0 [Pa], 1.0 [Pa], and 0.6 [Pa]. When the total pressure was set to 2.0 [Pa] (“∘” in FIG. 11), the residual stress fell within a range of −200 [MPa] to +60 [MPa] even when the O2 flow rate was changed to 2 [sccm] to 8 [sccm].

In contrast thereto, when the total pressure was set to 1.0 [Pa], the residual stress of both directions of the X-direction and the Y-direction fell within a range of −400 [MPa] to −200 [MPa] only when the O2 flow rate was set to 2 [sccm]. However, when the O2 flow rate was set to 3.5 [sccm] or 5 [sccm], the residual stress departed from a range of −400 [MPa] to +400 [MPa] in both directions or one direction of the X-direction and the Y-direction.

Moreover, when the total pressure was set to 0.6 [Pa], the residual stress departed from the range of −400 [MPa] to +400 [MPa] in both directions or one direction of the X-direction and the Y-direction whichever of 2 [sccm], 5 [sccm], and 8 [sccm] the O2 flow rate was set to.

A condition other than the condition illustrated in FIG. 11 may be employed. Specifically, a condition other than the present check condition may be employed regarding the O2 flow rate. In the case of employing such a condition, the residual stress of the translucent electrically-conductive film 109 is measured in advance and whether or not the employment is possible can be decided.

Furthermore, in the above-described check, the case in which the translucent electrically-conductive film composed of IZO is used is employed. However, in the case of employing another material (for example, ITO or zinc oxide-based material) and so forth, a similar effect can be obtained by setting the optimum film deposition condition. For example, in the case of employing the translucent electrically-conductive film composed of ITO, a similar effect can be obtained by setting the total pressure in the film deposition to 2.0 [Pa].

Moreover, in the case of employing the translucent electrically-conductive film composed of the zinc oxide-based material, the residual stress can be made to fall within a range of −200 [MPa] to +40 [MPa] by setting the total pressure in the film deposition to 0.6 [Pa] and setting the O2 flow rate to 5 [sccm].

### Embodiment 2

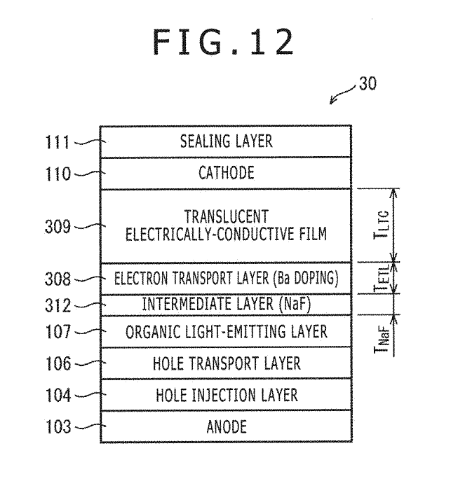

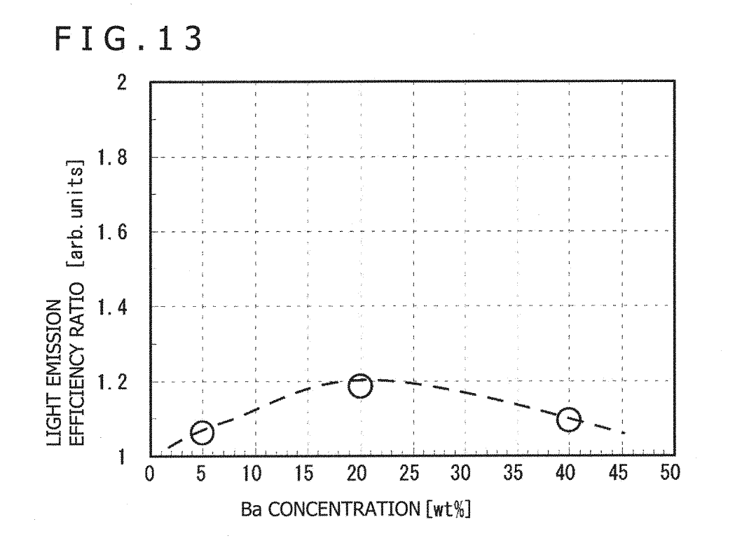

The configuration and so forth of a display panel 30 according to embodiment 2 will be described by using FIG. 12 and FIG. 13 and furthermore [Table 3], [Table 4], and [Table 5] indicated below.

### 1. Schematic Configuration of Display Panel 30

As illustrated in FIG. 12, the display panel 30 according to the present embodiment has a configuration in which, between the organic light-emitting layer 107 and the cathode 110, an intermediate layer 312, an electron transport layer 308, and a translucent electrically-conductive film 309 are interposed from the side of the organic light-emitting layer 107, and is similar to the above-described embodiment 1 regarding the other configuration.

The intermediate layer 312 according to the present embodiment is composed of sodium fluoride (NaF). However, as the constituent material of the intermediate layer, a material other than it can also be employed as long as it is a fluoride of an alkali metal or an alkaline earth metal. It suffices for film thickness TNaF of the intermediate layer 312 to be in a range of approximately 1 [nm] to 4 [nm], and the film thickness TNaF is set to 4 [nm] as one example.

Next, the electron transport layer 308 according to the present embodiment is a layer obtained by doping an organic material similar to the electron transport layer 108 according to the above-described embodiment with barium (Ba). However, regarding the doping element, it is also possible to employ an alkali metal or an alkaline earth metal other than Ba. For example, as the employable metal element other than Ba, lithium (Li), calcium (Ca), potassium (K), cesium (Cs), sodium (Na), rubidium (Rb), and so forth can be cited.

The doping concentration is set in a range of 5 [wt %] to 40 [wt %]. In particular, in the present embodiment, the doping concentration is set to 40 [wt %] as one example.

The translucent electrically-conductive film 309 is a film that is composed of indium tin oxide (ITO) or indium zinc oxide (IZO) or a zinc oxide-based material and has translucency and electrical conductivity. In the present embodiment, film thickness TLTC of the translucent electrically-conductive film 309 is set to 105 [nm].

Also in the present embodiment, the residual stress of the translucent electrically-conductive film 309 is set in a range of −400 [MPa] to +400 [MPa], more preferably −200 [MPa] to +200 [MPa], and further preferably in a range of −200 [MPa] to +60 [MPa].

### 2. Effects

In the display panel 30, the film thickness TLTC of the translucent electrically-conductive film 309 is set to 60 [nm] or larger. Furthermore, the residual stress thereof is prescribed in the similar range to the above-described embodiment 1. This provides the similar effects to the above-described embodiment 1. That is, also in the display panel 30, the occurrence of a film defect of the electron transport layer 308 under the translucent electrically-conductive film 309 can be suppressed while the occurrence of cathode quenching is suppressed by disposing the translucent electrically-conductive film 309 between the cathode 110 and the electron transport layer 308.

Furthermore, in the display panel 30 according to the present embodiment, the intermediate layer 312 composed of NaF is inserted and a layer obtained by doping with Ba is employed as the electron transport layer 308. Therefore, more favorable light emission characteristics can be realized. Specifically, due to the insertion of the intermediate layer 312 composed of NaF, entry of impurities from the side of the organic light-emitting layer 107 into the electron transport layer 308 is blocked. Thus, favorable storage stability can be realized.

Moreover, due to the employment of the electron transport layer 308 obtained by being doped with Ba, the electron transport layer 308 plays a role in breaking the bond between Na and F for NaF configuring the intermediate layer 312 and Na can be released in the intermediate layer 312. Furthermore, the alkali metal or the alkaline earth metal typified by Ba has a low work function and high electron injection properties and thus allows sufficient electron supply to the organic light-emitting layer 107.

### 3. Doping Concentration of Ba and Respective Film Thicknesses TLTC, TETL, and TNaF

The doping concentration of Ba in the electron transport layer 308 was set to 5 [wt %], 20 [wt %], and 40 [wt %] and evaluation for each light extraction efficiency was carried out, with the film thickness TLTC changed in a range of 0 [nm] to 105 [nm] and with the TETL changed in a range of 10 [nm] to 115 [nm]. The results thereof are indicated in [Table 3], [Table 4], and [Table 5].

TABLE 3

| | Film thickness (nm) | | Ba concentration | Light extraction |
|---|---|---|---|---|
| Red | T_{LTC} | T_{ETL} | (wt %) | efficiency (%) |
| 21 | 105 | 10 | 5 | 100 |
| 22 | 105 | 10 | 20 | 96 |
| 23 | 105 | 10 | 40 | 92 |
| 24 | 95 | 20 | 5 | 99 |
| 25 | 95 | 20 | 20 | 88 |
| 26 | 95 | 20 | 40 | 79 |
| 27 | 85 | 35 | 5 | 94 |
| 28 | 85 | 35 | 20 | 74 |
| 29 | 85 | 35 | 40 | 53 |

TABLE 4

| | Film thickness (nm) | | Ba concentration | Light extraction |
|---|---|---|---|---|
| Green | T_{LTC} | T_{ETL} | (wt %) | efficiency (%) |
| 31 | 105 | 10 | 5 | 100 |
| 32 | 105 | 10 | 20 | 100 |
| 33 | 105 | 10 | 40 | 97 |
| 34 | 95 | 20 | 5 | 100 |
| 35 | 95 | 20 | 20 | 96 |
| 36 | 95 | 20 | 40 | 95 |
| 37 | 85 | 35 | 5 | 94 |
| 38 | 85 | 35 | 20 | 87 |
| 39 | 85 | 35 | 40 | 85 |

TABLE 5

| | Film thickness (nm) | | Ba concentration | Light extraction |
|---|---|---|---|---|
| Blue | T_{LTC} | T_{ETL} | (wt %) | efficiency (%) |
| 41 | 105 | 10 | 5 | 100 |
| 42 | 105 | 10 | 20 | 93 |
| 43 | 105 | 10 | 40 | 89 |
| 44 | 95 | 20 | 5 | 100 |
| 45 | 95 | 20 | 20 | 92 |
| 46 | 95 | 20 | 40 | 82 |
| 47 | 85 | 35 | 5 | 98 |
| 48 | 85 | 35 | 20 | 89 |
| 49 | 85 | 35 | 40 | 79 |
| 50 | 50 | 65 | 5 | 90 |
| 51 | 50 | 65 | 20 | 66 |
| 52 | 50 | 65 | 40 | 62 |
| 53 | 0 | 115 | 5 | 73 |
| 54 | 0 | 115 | 20 | 47 |
| 55 | 0 | 115 | 40 | 29 |

### (i) Red (R)

First, the result of the evaluation with the light-emitting device of red (R) will be described by using [Table 3].

As indicated in [Table 3], high light extraction efficiency of 94[%] to 100 [%] was obtained in samples 21, 24, and 27, in which the doping concentration of Ba was set to 5 [wt %]. Furthermore, among them, sample 21, in which TLTC was as thick as 105 [nm] and TETL was as thin as 10 [nm], could obtain the highest light extraction efficiency.

Also regarding samples 22, 25, and 28, in which the doping concentration of Ba was 20 [wt %], and samples 23, 26, and 29, in which the doping concentration was 40 [wt %], the light extraction efficiency became lower as TETL became thicker. Furthermore, the light extraction efficiency became lower as the doping concentration of Ba became higher.

### (ii) Green (G)

Next, the result of the evaluation with the light-emitting device of green (G) will be described by using [Table 4].

As indicated in [Table 4], high light extraction efficiency not lower than 90 [%] was obtained in samples 31 to 37. Also in green, particularly in samples 31 and 32, in which TLTC was as thick as 105 [nm] and TETL was as thin as 10 [nm], light extraction efficiency of 100[%] was obtained when the doping concentration of Ba was 5 [wt %] and 20 [wt %].

Also in the light-emitting device of green, the light extraction efficiency became lower as TETL became thicker, and the light extraction efficiency became lower as the doping concentration of Ba became higher.

(iii) Blue (B)

Next, the result of the evaluation with the light-emitting device of blue (B) will be described by using [Table 5].

As indicated in [Table 5], high light extraction of 100[%] was obtained regarding samples 41 and 44, in which the doping concentration of Ba was 5 [wt %].

As for TLTC, the light extraction efficiency in samples 41 to 43, in which TLTC was 105 [nm], was high, whereas the light extraction efficiency was low in samples 53 to 55, in which the translucent electrically-conductive film was not inserted.

Also in the light-emitting device of blue, the light extraction efficiency became lower as TETL became thicker, and the light extraction efficiency became lower as the doping concentration of Ba became higher.

### (iv) Consideration

In each color of red (R), green (G), and blue (B), the result in which the light extraction efficiency decreased as the doping concentration of Ba was increased was obtained. The inventors infer that this was because part of emitted light was absorbed by Ba with which the electron transport layer 308 was doped.

Furthermore, the result in which the light extraction efficiency decreased as TETL, i.e. the film thickness of the electron transport layer, was increased was obtained. This is presumed to be because light was absorbed due to the increase in the film thickness of the electron transport layer, which was an organic film, and the decrease in the light extraction efficiency was caused.

The evaluation result for the relationship between the doping concentration of Ba and the light emission efficiency ratio is illustrated in FIG. 13. The criterion in the light emission efficiency ratio was the light emission efficiency in the case in which doping with Ba was not carried out.

As illustrated in FIG. 13, the light emission efficiency ratio surpassed “1” whichever of 5 [wt %], 20 [wt %], and 40 [wt %] the doping concentration was. In particular, the light emission efficiency ratio exhibited a high value of “1.2” when the doping concentration was 20 [wt %].

From this, it suffices for the doping concentration of Ba in the electron transport layer to be in a range of 5 [wt %] to 40 [wt %]. In particular, it can be said that the electron transport layer is excellent in terms of the light emission efficiency ratio when the doping concentration is approximately 20 [wt %]. It is inferred that this is similar even with an alkali metal or an alkaline earth metal other than Ba.

### Embodiment 3

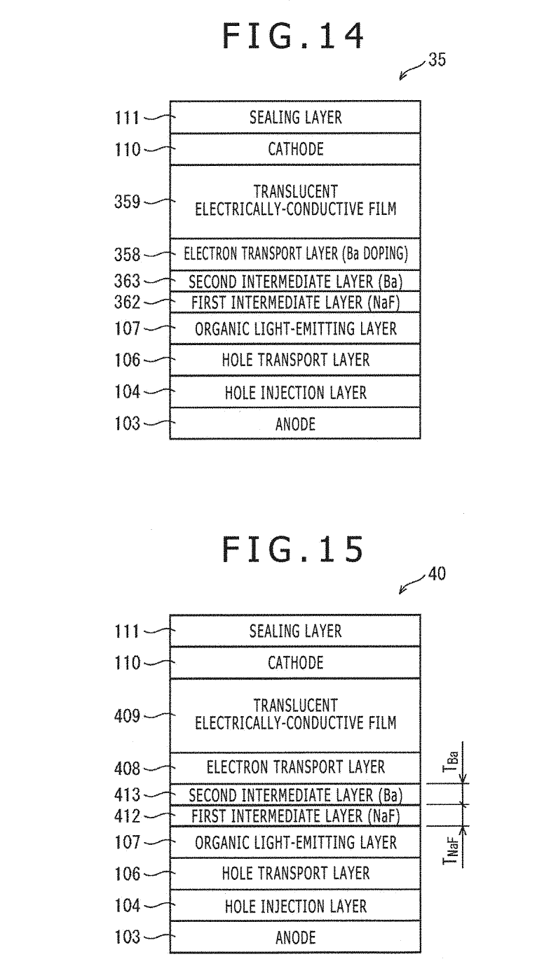

The configuration of a display panel 35 according to embodiment 3 will be described by using FIG. 14.

### 1. Schematic Configuration of Display Panel 35

As illustrated in FIG. 14, the display panel 35 according to the present embodiment has a configuration in which, between the organic light-emitting layer 107 and the cathode 110, a first intermediate layer 362, a second intermediate layer 363, an electron transport layer 358, and a translucent electrically-conductive film 359 are interposed from the side of the organic light-emitting layer 107. The display panel 35 is similar to the above-described embodiment 2 regarding the configuration of the translucent electrically-conductive film 359 and the other configuration.

The first intermediate layer 362 according to the present embodiment is composed of sodium fluoride (NaF) similarly to the intermediate layer 312 of the above-described embodiment 2. Also in the present embodiment, as the constituent material of the first intermediate layer 362, a material other than it can also be employed as long as it is a fluoride of an alkali metal or an alkaline earth metal. Also regarding the film thickness of the first intermediate layer 362, it suffices for the film thickness to be in a range of approximately 1 [nm] to 4 [nm], and the film thickness is set to 4 [nm] as one example.

Next, the second intermediate layer 363 is a thin film composed of Ba. However, the second intermediate layer 363 may be formed by using an alkali metal or an alkaline earth metal other than Ba. The film thickness of the second intermediate layer 363 is 1 [nm], for example.

Next, the electron transport layer 358 is a layer obtained by doping an organic material similar to the electron transport layer 308 according to the above-described embodiment 2 with barium (Ba). Also in the electron transport layer 358, it is also possible to employ an alkali metal or an alkaline earth metal other than Ba regarding the doping element. For example, as the employable metal element other than Ba, lithium (Li), calcium (Ca), potassium (K), cesium (Cs), sodium (Na), rubidium (Rb), and so forth can be cited.

The doping concentration is set in a range of 5 [wt %] to 20 [wt %]. In particular, in the present embodiment, the doping concentration is set to 20 [wt %] as one example.

Here, also in the present embodiment, the film thickness of the translucent electrically-conductive film 359 is set to 105 [nm]. Furthermore, also in the present embodiment, the residual stress of the translucent electrically-conductive film 359 is set in a range of −400 [MPa] to +400 [MPa], more preferably −200 [MPa] to +200 [MPa], and further preferably in a range of −200 [MPa] to +60 [MPa].

### 2. Effects

Also in the display panel 35, the film thickness of the translucent electrically-conductive film 359 is set to 60 [nm] or larger. Furthermore, the residual stress thereof is prescribed in the similar range to the above-described embodiment 1. Thus, the similar effects to the above-described embodiments 1 and 2 are provided. That is, also in the display panel 35, the occurrence of a film defect of the electron transport layer 358 under the translucent electrically-conductive film 359 can be suppressed while the occurrence of cathode quenching is suppressed by disposing the translucent electrically-conductive film 359 between the cathode 110 and the electron transport layer 358.

Furthermore, also in the display panel 35 according to the present embodiment, the first intermediate layer 362 composed of NaF is inserted and a thin film composed of Ba is inserted as the second intermediate layer 363, and a layer obtained by being doped with Ba is employed as the electron transport layer 358. Therefore, more favorable light emission characteristics can be realized. Specifically, due to the insertion of the first intermediate layer 362 composed of NaF, entry of impurities from the side of the organic light-emitting layer 107 into the electron transport layer 358 is blocked. Thus, favorable storage stability can be realized.

Moreover, due to the insertion of the second intermediate layer 363 composed of Ba and the employment of the electron transport layer 358 obtained by being doped with Ba, these layers play a role in breaking the bond between Na and F for NaF configuring the first intermediate layer 362 and Na can be released in the first intermediate layer 362. Furthermore, the alkali metal or the alkaline earth metal typified by Ba has a low work function and high electron injection properties and thus allows sufficient electron supply to the organic light-emitting layer 107.

### Embodiment 4

The configuration and so forth of a display panel 40 according to embodiment 4 will be described by using FIG. 15 to FIG. 19.

### 1. Schematic Configuration of Display Panel 40

As illustrated in FIG. 15, also in the display panel 40 according to the present embodiment, a configuration is made in which, between the organic light-emitting layer 107 and the cathode 110, a first intermediate layer 412, a second intermediate layer 413, an electron transport layer 408, and a translucent electrically-conductive film 409 are interposed from the side of the organic light-emitting layer 107. The display panel 40 is similar to the above-described embodiment 3 regarding the respective configurations of the first intermediate layer 412, the second intermediate layer 413, and the translucent electrically-conductive film 409 and the other configuration.

For the electron transport layer 408 according to the present embodiment, doping of an organic material with an alkali metal or an alkaline earth metal is not carried out differently from the electron transport layers 308 and 358 according to the above-described embodiments 2 and 3.

Also in the present embodiment, the film thickness of the translucent electrically-conductive film 409 is set to 105 [nm]. Furthermore, the residual stress of the translucent electrically-conductive film 409 is set in a range of −400 [MPa] to +400 [MPa], more preferably −200 [MPa] to +200 [MPa], and further preferably in a range of −200 [MPa] to +60 [MPa].

### 2. Effects

Also in the display panel 40, the film thickness of the translucent electrically-conductive film 409 is set to 60 [nm] or larger. Furthermore, the residual stress thereof is prescribed in the similar range to the above-described embodiment 1. Thus, the similar effects to the above-described embodiments 1 to 3 are provided. That is, also in the display panel 40, the occurrence of a film defect of the electron transport layer 408 under the translucent electrically-conductive film 409 can be suppressed while the occurrence of cathode quenching is suppressed by disposing the translucent electrically-conductive film 409 between the cathode 110 and the electron transport layer 408.

Furthermore, also in the display panel 40 according to the present embodiment, the first intermediate layer 412 composed of NaF is inserted and a thin film composed of Ba is inserted as the second intermediate layer 413. Therefore, favorable light emission characteristics can be realized. Specifically, due to the insertion of the first intermediate layer 412, entry of impurities from the side of the organic light-emitting layer 107 into the electron transport layer 408 is blocked. Thus, favorable storage stability can be realized.

Moreover, due to the insertion of the second intermediate layer 413 composed of Ba, the second intermediate layer 413 plays a role in breaking the bond between Na and F for NaF configuring the first intermediate layer 412 and Na can be released in the first intermediate layer 412. Furthermore, the alkali metal or the alkaline earth metal typified by Ba has a low work function and high electron injection properties and thus allows sufficient electron supply to the organic light-emitting layer 107.

### 3. Consideration Concerning First Intermediate Layer 412 and Second Intermediate Layer 413

### (i) Second Intermediate Layer 413

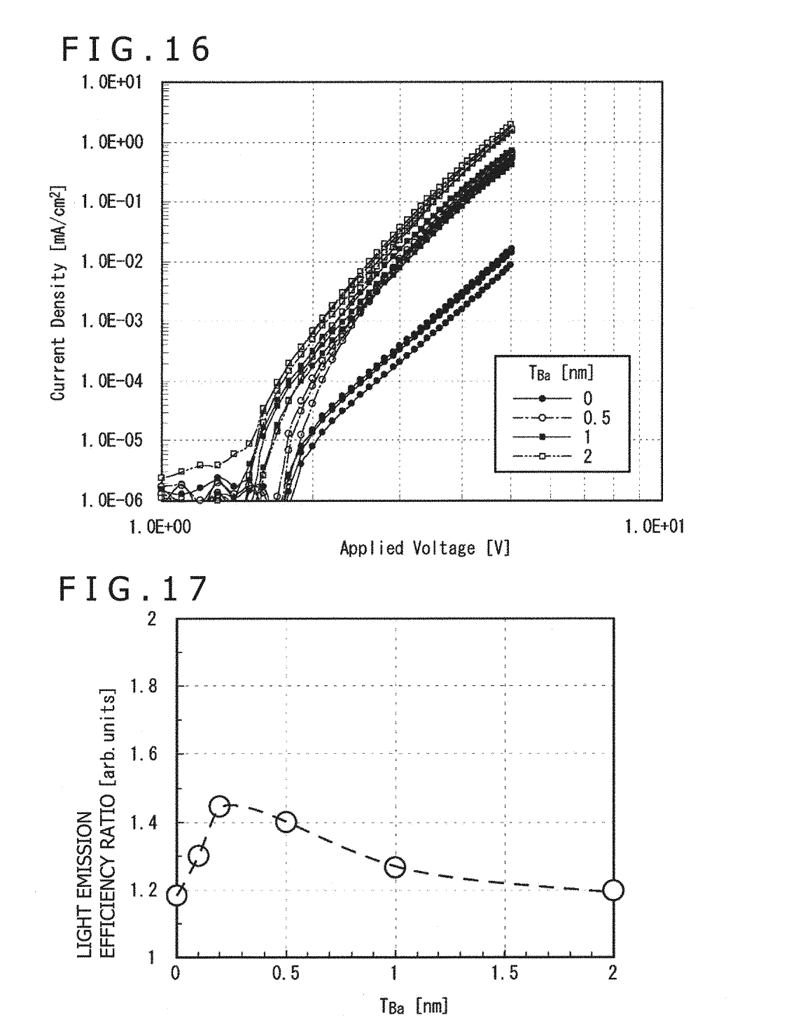

A result of consideration concerning the second intermediate layer 413 will be described by using FIG. 16 and FIG. 17.

First, FIG. 16 illustrates the measurement result of the current density of samples prepared in such a manner that film thickness TNaF of the first intermediate layer 412 was set to 4 [nm] and film thickness TBa of the second intermediate layer 413 was changed to four kinds, 0 [nm] (without the second intermediate layer), 0.5 [nm], 1.0 [nm], and 2.0 [nm]. The measurement of the current density was carried out with plural samples.

As illustrated in FIG. 16, the respective samples whose TBa was 0.5 [nm], 1.0 [nm], and 2.0 [nm] all exhibited high current density relative to the samples in which the second intermediate layer was omitted. This will indicate that a large current flows between the cathode and the abode due to the insertion of the second intermediate layer 413. That is, a large current flows to the organic light-emitting layer 107 due to the insertion of the second intermediate layer 413, which enables light emission with high luminance.

Among the samples, the samples whose TBa was 2.0 [nm] exhibited the highest current density. However, a large difference comparable to the difference of the current density in the three kinds of samples in which the second intermediate layer was inserted with respect to the samples in which the second intermediate layer was omitted was not found.

From the above, regarding the film thickness TBa of the second intermediate layer 413, it turns out that the display panel 40 is excellent in terms of high current density if the film thickness TBa is at least 0.5 [nm].

Next, FIG. 17 illustrates the light emission efficiency ratio of each of samples prepared in such a manner that the film thickness TBa of the second intermediate layer 413 was changed to six kinds, 0 [nm] (without the second intermediate layer), 0.1 [nm], 0.2 [nm], 0.5 [nm], 1.0 [nm], and 2.0 [nm]. Regarding the light emission efficiency ratio illustrated in FIG. 17, the light emission luminance when a voltage was applied to cause the current density to become 10 [mA/cm2] was measured and the light emission efficiency was calculated from the measured light emission luminance value. Furthermore, a conventional organic light-emission device was employed as the criterion and the light emission efficiency ratio of each sample was calculated and plotted. Also when the result of FIG. 17 was obtained, the film thickness TNAF of the first intermediate layer 412 was set to 4 [nm].

As illustrated in FIG. 17, the sample in which the film thickness TBa of the second intermediate layer 413 was 0.2 [nm] exhibited the highest light emission efficiency ratio. Furthermore, the sample whose film thickness TBa was 2.0 [nm] exhibited a low light emission efficiency ratio substantially equivalent to that in the sample in which the second intermediate layer was omitted (TBa=0 [nm]). Regarding this, the inventors infer that, when excess electrons relative to holes were injected into the organic light-emitting layer 107 whereas the amount of holes injected from the hole injection layer 104 into the organic light-emitting layer 107 was constant, the light emission luminance did not increase in association with increase in the current and as a result the low light emission efficiency ratio was obtained.

From the result illustrated in FIG. 17, it can be said that 0.1 [nm]≦TBa≦1.0 [nm] is a preferable range to obtain a high light emission efficiency ratio. Furthermore, in the case of assuming a display panel of the top-emission type, setting TBa≦1.0 [nm] can suppress the amount of light absorption in the second intermediate layer 413 to a low value and obtain excellent light extraction performance.

### (ii) First Intermediate Layer 412

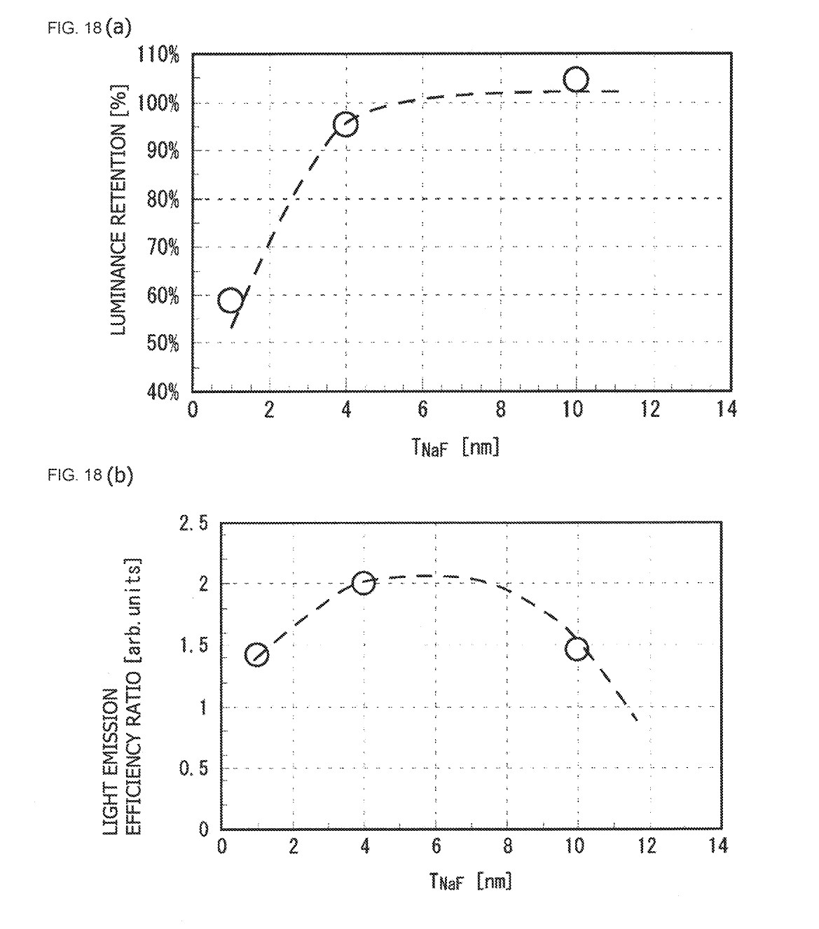

Next, a result of consideration concerning the first intermediate layer 412 will be described by using FIG. 18.

First, in FIG. 18(a), a result of a storage stability test in each sample in the case in which the film thickness TNaF of the first intermediate layer 412 was changed to three kinds, 1.0 [nm], 4.0 [nm], and 10.0 [nm], is represented. Regarding the storage stability, evaluation was carried out by using the light emission luminance retention after storage at a high temperature. Specifically, the following evaluation was carried out.

A current was made to flow in each sample and the initial light emission luminance was measured

The samples were stored for seven days under an environment at 80 [° C.]

A current was made to flow in each sample again and the light emission luminance was measured

Then, the measured luminance value after the storage at the high temperature with respect to the initial measured luminance value was calculated.

As illustrated in FIG. 18(a), luminance retention of 59[%] was exhibited in the sample in which the film thickness TNaF of the first intermediate layer 412 was 1.0 [nm], whereas luminance retention of 95[%] or higher was exhibited in the sample in which the film thickness TNaF was 4.0 [nm] and the sample in which the film thickness TNaF was 10.0 [nm].

As illustrated in FIG. 18(a), a result in which the luminance retention surpassed 100[%] was obtained in the sample in which the film thickness TNaF was 10.0 [nm]. It is conceivable that the cause of this was that the injection balance between holes and electrons had deviated from the optimum state in the initial state but was optimized through the storage under the high-temperature environment. That is, it is conceivable that the storage served as a substitute for aging.

From the above, in terms of the storage stability, it will be preferable for the film thickness TNaF of the first intermediate layer 412 to be at least 4.0 [nm] or larger.

Next, in FIG. 18(b), the light emission efficiency ratio of each sample in the case in which the film thickness TNaF of the first intermediate layer 412 was changed to three kinds, 1.0 [nm], 4.0 [nm], and 10.0 [nm], is represented. For the light emission efficiency ratio represented in FIG. 18(b), the light emission luminance when a voltage was applied to cause the current density to become 10 [mA/cm2] was measured and the light emission efficiency was calculated from the measured light emission luminance value. Furthermore, a conventional organic light-emission device was employed as the criterion and the light emission efficiency ratio of each sample was calculated and plotted.

As illustrated in FIG. 18(b), in the sample whose film thickness TNaF was 4.0 [nm] in the three kinds of samples, the highest light emission efficiency ratio was exhibited. Furthermore, it turns out that the light emission efficiency ratio became low if the film thickness TNaF of the first intermediate layer 412 was smaller than 1.0 [nm] and when the film thickness TNaF was larger than 10.0 [nm]. It is conceivable that this is because the absolute amount of released Na becomes small and the movement of electrons from the electron transport layer 408 to the organic light-emitting layer 107 is not promoted when the film thickness TNaF of the first intermediate layer 412 becomes smaller than 1.0 [nm]. Conversely, it is conceivable that the function as an insulating layer intensely works and the lowering of the light emission efficiency is caused when the film thickness TNaF becomes larger than 10.0 [nm].

Therefore, it will be preferable for the film thickness TNaF of the first intermediate layer 412 to be set in a range of 1.0 [nm] to 10.0 [nm].

(iii) Ratio Between Film Thickness TNaF of First Intermediate Layer 412 and Film Thickness TBa of Second Intermediate Layer 413

As described above, regarding the film thickness TNaF of the first intermediate layer 412, the above-described minimum film thickness is necessary to ensure the function of blocking entry of impurities from the side of the organic light-emitting layer 107 into the electron transport layer 408.

On the other hand, if the film thickness TNaF of the first intermediate layer 412 is set too large, nature as an insulating film becomes strong and electron injection properties to the organic light-emitting layer 107 are lowered. For this reason, the case in which sufficient light emission luminance is not obtained possibly occurs.

Furthermore, if the film thickness TBa of the second intermediate layer 413 is set too small, Ba that configures the second intermediate layer 413 becomes incapable of sufficiently exerting the function of releasing Na included in the configuration of the first intermediate layer 412 from F, so that it becomes impossible to supply sufficient electrons to the organic light-emitting layer 107.

On the other hand, if the film thickness TBa of the second intermediate layer 413 is set too large, excess electrons are supplied to the organic light-emitting layer 107 with respect to the amount of holes supplied to the organic light-emitting layer 107, which causes the lowering of the light emission efficiency.

Moreover, if the film thickness TBa of the second intermediate layer 413 is set too large relative to the film thickness TNaF of the first intermediate layer 412, this leads to a result in which Ba excessively releases Na in the first intermediate layer 412, and there is a fear that reduction in NaF is caused and it becomes impossible to sufficiently achieve the impurity blocking performance in the first intermediate layer 412.

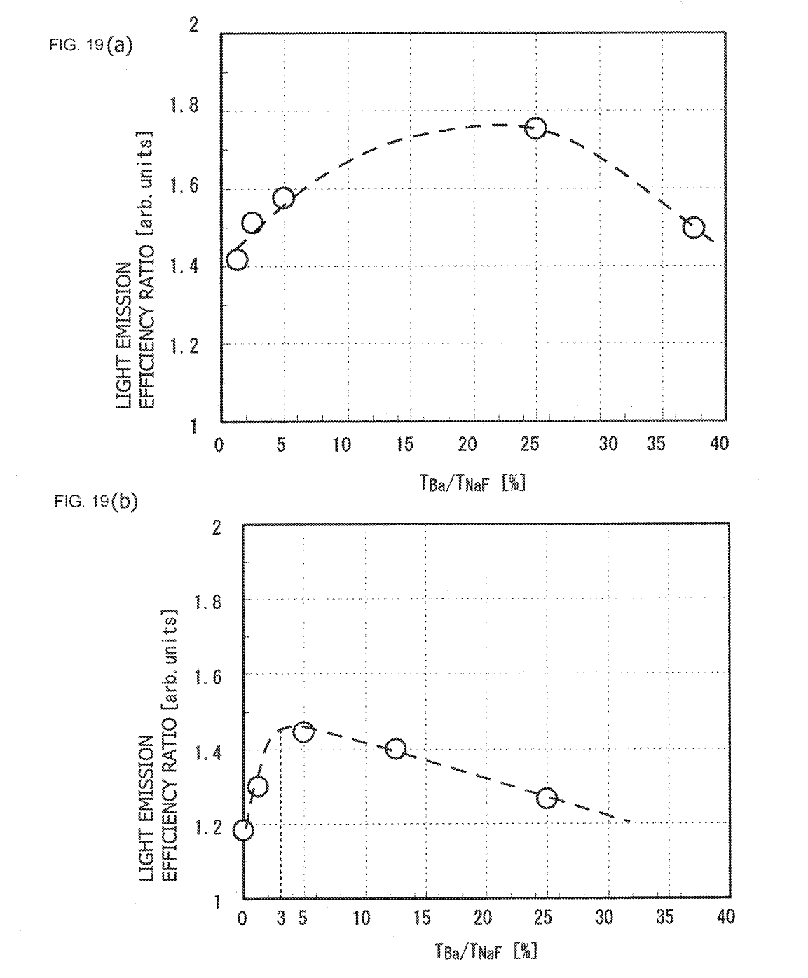

From the above consideration, the present inventors have reached the conclusion that, regarding the first intermediate layer 412 and the second intermediate layer 413, the ranges of the optimum film thicknesses TNaF and TBa for the respective layers do not only exist but the optimum range exists also regarding the ratio between them. Therefore, the present inventors changed the ratio of the film thickness TBa of the second intermediate layer 413 to the film thickness TNaF of the first intermediate layer 412 and made consideration concerning how the light emission efficiency ratio was affected. The result thereof is illustrated in FIGS. 19(a) and (b).

FIG. 19(a) and FIG. 19(b) were obtained through changing the constituent material of the hole injection layer 104 from each other. As the constituent material of the hole injection layer 104 in each sample used for FIG. 19(a), a material having higher hole supply capability than the constituent material of the hole injection layer 104 in each sample used for FIG. 19(b) was employed.

In FIG. 19(a), the light emission efficiency ratio of each sample is represented regarding samples in which the film thickness ratio TBa/TNaF was changed to five kinds, 1.25[%], 2.0[%], 5.0[%], 25.0[%], and 37.5[%].

As illustrated in FIG. 19(a), in the case in which the hole injection layer 104 was formed by using the material whose hole supply capability was comparatively high, the light emission efficiency ratio was high with the film thickness ratio TBa/TNaF in a range of 20[%] to 25[%].

Next, in FIG. 19(b), the light emission efficiency ratio of each sample is represented regarding samples in which the film thickness ratio TBa/TNaF was changed to five kinds, 0[%] (without the second intermediate layer), 1.25[%], 5.0[%], 12.5[%], and 25.0[%].

As illustrated in FIG. 19(b), in the case in which the hole injection layer 104 was formed by using the material whose hole supply capability was comparatively low, the light emission efficiency ratio was high with the film thickness ratio TBa/TNaF in a range of 3[%] to 5[%].

When consideration is comprehensively made from the above results, a high light emission efficiency ratio can be obtained when the film thickness ratio TBa/TNaF is set in a range of 3[%] to 25[%]. That is, excellent light emission efficiency will be obtained by setting the film thickness ratio TBa/TNaF in the range of 3[%] to 25 [%].

Regarding the boundary part between the first intermediate layer 412 and the second intermediate layer 413, it is conceivable that there is also the case in which a clear boundary surface does not exist and NaF configuring the first intermediate layer 412 and Ba configuring the second intermediate layer 413 somewhat mix with each other in the process of the manufacturing. In such a case, if the component ratio (molar ratio) between Ba and NaF is in a range of 1[%]≦Ba/NaF≦10[%], the configuration will be preferable in terms of obtaining favorable light emission efficiency.

Furthermore, although the present consideration has been made concerning the configuration of embodiment 4, the consideration will be similar also in the case of the configuration of the above-described embodiment 3.

### Embodiment 5

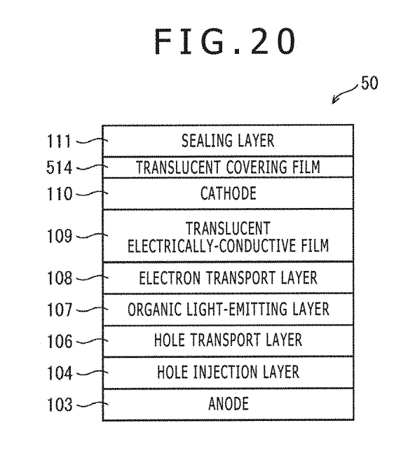

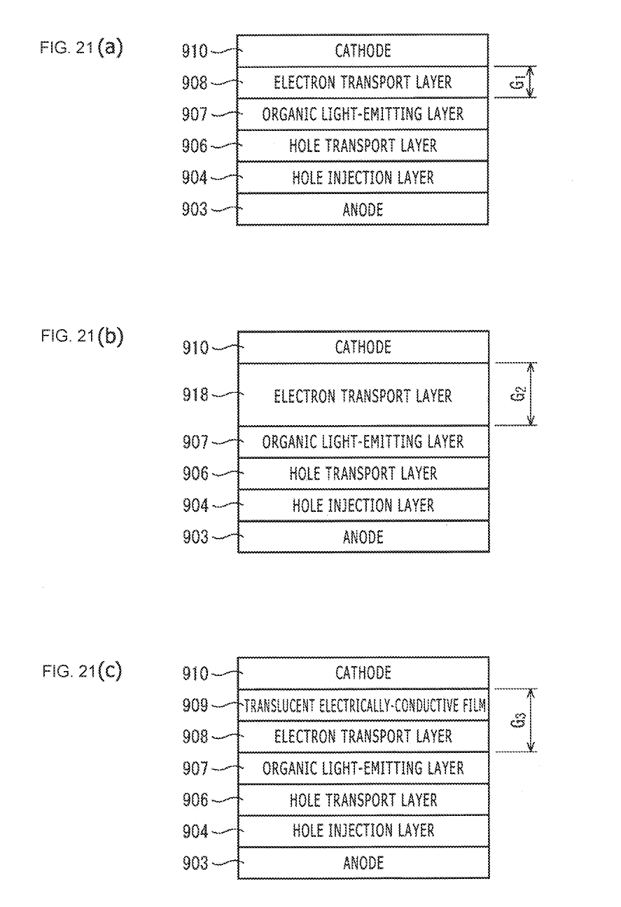

The configuration of a display panel 50 according to embodiment 5 will be described by using FIG. 20.

As illustrated in FIG. 20, a display panel 50 according to the present embodiment has characteristics in that a translucent covering film 514 is inserted between the cathode 110 and the sealing layer 111 for the display panel 10 of the above-described embodiment 1. The translucent covering film 514 is composed of a material having translucency. As materials that can be used, for example, indium tin oxide (ITO) and indium zinc oxide (IZO) or zinc oxide-based materials (materials containing zinc oxide as the main component) or the like and furthermore resin materials or the like can be cited.

Regarding the zinc oxide-based material, a material obtained by adding, to zinc oxide, e.g. at least one kind of element among tin (Sn), indium (In), gallium (Ga), magnesium (Mg), calcium (Ca), aluminum (Al), silicon (Si), thallium (TI), bismuth (Bi), and lead (Pb) can be employed as with the above description.

Although not described in detail, also in the display panel 50, the film thickness of the translucent electrically-conductive film 109 is set to 60 [nm] or larger. Furthermore, the residual stress thereof is prescribed in the similar range to the above-described embodiment 1. Thus, the similar effects to the above-described embodiments 1 to 4 are provided. That is, also in the display panel 50, the occurrence of a film defect of the electron transport layer 108 under the translucent electrically-conductive film 109 can be suppressed while the occurrence of cathode quenching is suppressed by disposing the translucent electrically-conductive film 109 between the cathode 110 and the electron transport layer 108.

Furthermore, in the display panel 50 according to the present embodiment, protection of the cathode 110 formed of a metal thin film can be intended more surely by covering the upper surface of the cathode 110 by the translucent covering film 514. Thus, stabilization of light emission quality over a long period can be intended.

### Other Matters

In the above-described embodiments 1 to 5, a display of the top-emission type is used as one example of an organic light-emitting device. However, the present invention is not limited by this. For example, the present invention can be applied also to a display in which light is emitted from both the top side and the bottom side, and so forth.

Furthermore, the present invention can be applied to not only a display panel but also an illuminating device.

Moreover, in the above-described embodiments 1 to 5, the configuration in which the cathode 110 is disposed on the light extraction side and the anode 103 is disposed on the opposite side is employed. However, the present invention is not limited by this. It is also possible to employ a form in which the anode is disposed on the light extraction side and the cathode is disposed on the opposite side.

Furthermore, it is also possible to employ an electrode using a light-transmissive material or employ a semi-transmissive electrode, or the like, regarding the electrode disposed on the lower side in the Z-axis direction.

Moreover, in the above-described embodiments 1 to 5, the configuration in which the hole injection layer 104 and the hole transport layer 106 are inserted between the anode 103 and the organic light-emitting layer 107 is employed as one example. However, these layers are not essential configurations. For example, it is also possible to configure the hole injection layer and the hole transport layer by a single layer, or the like.

Moreover, although a display having a flat plate shape is employed as one example in the above-described embodiments 1 to 5, it is also possible to employ a display having a curved surface shape. Furthermore, in the case of employing a resin substrate, it is also possible to employ a display having flexibility.

### INDUSTRIAL APPLICABILITY

The present invention is useful to implement an organic light-emitting device having excellent light emission efficiency.

### REFERENCE SIGNS LIST

1. Organic EL display device
10, 30, 35, 40. Display panel
10a to 10c. Sub-pixel
10d. Non-light-emitting region
20. Control drive circuit part
21 to 24. Drive circuit
25. Control circuit
100. Substrate
101. TFT layer
102. Insulating layer
103. Anode
104. Hole injection layer
105. Bank
106. Hole transport layer
107. Organic light-emitting layer
108, 308, 358, 408. Electron transport layer
109, 309, 359, 409. Translucent electrically-conductive film
110. Cathode
111. Sealing layer
312. Intermediate layer
412, 362. First intermediate layer
413, 363. Second intermediate layer

1. An organic light-emitting device comprising:
a substrate;
a first electrode disposed over the substrate;
an organic light-emitting layer disposed over the first electrode;
an organic functional layer disposed over the organic light-emitting layer;
a translucent electrically-conductive film that is disposed on the organic functional layer and is in contact with the organic functional layer; and
a second electrode that is composed of a metal material or an alloy material and is disposed over the translucent electrically-conductive film,
wherein
in the translucent electrically-conductive film, film thickness is equal to or larger than 60 nm and residual stress is in a range of −400 MPa to +400 MPa.

2. The organic light-emitting device according to claim 1, wherein
the residual stress of the translucent electrically-conductive film is in a range of −200 MPa to +200 MPa.

3. The organic light-emitting device according to claim 1, wherein
the residual stress of the translucent electrically-conductive film is in a range of −200 MPa to +60 MPa.

4. The organic light-emitting device according to claim 1, wherein
distance from an interface in the organic light-emitting layer on a side of the first electrode to an interface in the second electrode on a side of the organic light-emitting layer and distance from the interface in the organic light-emitting layer on the side of the first electrode to an interface in the first electrode on the side of the organic light-emitting layer correspond to wavelength of light emitted from the organic light-emitting layer.

5. The organic light-emitting device according to claim 1, wherein
the film thickness of the translucent electrically-conductive film is larger than layer thickness of the organic functional layer.

6. The organic light-emitting device according to claim 1, wherein
an intermediate layer that contains a fluoride of an alkali metal or an alkaline earth metal and is in contact with the organic light-emitting layer is disposed between the organic light-emitting layer and the organic functional layer, and
the organic functional layer is a layer containing an organic material obtained by being doped with an alkali metal or an alkaline earth metal.

7. The organic light-emitting device according to claim 6, wherein
doping concentration of the alkali metal or the alkaline earth metal in the organic functional layer is equal to or higher than 20 wt % and is equal to or lower than 40 wt %.

8. The organic light-emitting device according to claim 6, wherein
a layer that contains an alkali metal or an alkaline earth metal and is in contact with the organic functional layer is disposed between the intermediate layer and the organic functional layer.

9. The organic light-emitting device according to claim 8, wherein
doping concentration of the alkali metal or the alkaline earth metal in the organic functional layer is equal to or higher than 5 wt % and is equal to or lower than 40 wt %.

10. The organic light-emitting device according to claim 1, wherein
a first intermediate layer that contains a fluoride of an alkali metal or an alkaline earth metal and is in contact with the organic light-emitting layer is disposed between the organic light-emitting layer and the organic functional layer, and
a second intermediate layer that contains an alkali metal or an alkaline earth metal and is in contact with both layers of the first intermediate layer and the organic functional layer is disposed between the first intermediate layer and the organic functional layer.

11. The organic light-emitting device according to claim 1, wherein
the second electrode is formed of Ag or MgAg or a layered body of them.

12. The organic light-emitting device according to claim 1, wherein
a major surface in the second electrode on an opposite side to the translucent electrically-conductive film is covered by a film having translucency.

13. The organic light-emitting device according to claim 1, wherein
the first electrode is also composed of a metal material or an alloy material and at least a major surface on the side of the organic light-emitting layer has light reflectivity.

14. The organic light-emitting device according to claim 1, wherein
the translucent electrically-conductive film is composed of indium tin oxide or indium zinc oxide.

15. The organic light-emitting device according to claim 1, wherein
the translucent electrically-conductive film is composed of a material containing zinc oxide as a main component.

16. The organic light-emitting device according to claim 15, wherein
the material containing the zinc oxide as the main component is a material obtained by adding, to zinc oxide, at least one kind of element among Sn, In, Ga, Mg, Ca, Al, Si, Tl, Bi, and Pb.

17. The organic light-emitting device according to claim 15, wherein
resistivity of the translucent electrically-conductive film is equal to or higher than 1×10² Ωcm and is equal to or lower than 1×10⁵ Ωcm.
